(19) United States
(12) Patent Application Publication
(10) Pub. No.: US 2024/0407234 A1
(43) Pub. Date: Dec. 5, 2024

(54) DISPLAY DEVICE AND METHOD OF FABRICATING THE SAME

(71) Applicant: Samsung Display Co., LTD., Yongin-si (KR)

(72) Inventor: Hyun Eok SHIN, Yongin-si (KR)

(73) Assignee: Samsung Display Co., LTD., Yongin-si (KR)

(21) Appl. No.: 18/418,486

(22) Filed: Jan. 22, 2024

(30) Foreign Application Priority Data
May 30, 2023 (KR) 10-2023-0069262

(51) Int. Cl. H10K 59/80; H10K 59/12; H10K 59/122; H10K 102/00

(52) U.S. Cl. CPC H10K 59/873; H10K 59/1201; H10K 59/122; H10K 2102/311; H10K 2102/351

(57) ABSTRACT

A display device includes a first pixel electrode disposed on a substrate, an inorganic insulating layer disposed on the substrate and exposing the first pixel electrode, a first light emitting layer disposed on the first pixel electrode, a first common electrode disposed on the first light emitting layer, a first bank layer disposed on the inorganic insulating layer, a second bank layer disposed on the first bank layer and having side surfaces protruding more than side surfaces of the first bank layer; and a first inorganic encapsulation layer disposed on an upper surface of the first common electrode, the side surfaces of the first bank layer, and lower and side surfaces of the second bank layer, and spaced apart from the side surfaces of the second bank layer.

### CROSS REFERENCE TO RELATED APPLICATION(S)

This application claims to and benefits of Korean Patent Application No. 10-2023-0069262, filed on May 30, 2023, in the Korean Intellectual Property Office, the entire contents of which are incorporated herein by reference.

### BACKGROUND

### 1. Technical Field

Embodiments relate to a display device and a method of fabricating the display device.

### 2. Description of the Related Art

As the information society develops, demands for display devices for displaying images have increased in various forms. For example, display devices are applied to various electronic devices such as smartphones, digital cameras, notebook computers, navigation devices, and smart televisions. The display devices may be flat panel display devices such as liquid crystal display devices, field emission display devices, and organic light emitting display devices. Among these flat panel display devices, a light emitting display device includes a light emitting element that enables each pixel of a display panel to emit light by itself. Thus, the light emitting display device may display an image without a backlight unit that provides light to the display panel.

Recently, display devices have been applied to glasses-like devices to provide virtual reality and augmented reality. To be applied to a glasses-like device, a display device is implemented in a very small size of 2 inches or less. However, the display device should have a high pixel density to have a high resolution. For example, the display device may have a high pixel density of 200 pixels per inch (PPI) or more.

In case that a display device is implemented in a very small size but has a high pixel density as described above, it is difficult to implement separated light emitting elements in each emission area by a mask process because the area of the emission area in which the light emitting element is disposed is reduced.

### SUMMARY

Embodiments provide a display device in which separated light emitting elements are formed in each emission area without a mask process.

Embodiments also provide a display device in which an encapsulation layer maintains a stable structure without being peeled off during a fabrication process of the display device, and a method of fabricating the display device.

However, embodiments are not limited to those set forth herein. The above and other embodiments will become more apparent to one of ordinary skill in the art to which the disclosure pertains by referencing the detailed description of the disclosure given below.

According to an aspect of the disclosure, a display device may include a first pixel electrode disposed on a substrate, an inorganic insulating layer disposed on the substrate and exposing the first pixel electrode, a first light emitting layer disposed on the first pixel electrode, a first common electrode disposed on the first light emitting layer, a first bank layer disposed on the inorganic insulating layer, a second bank layer disposed on the first bank layer and including side surfaces protruding more than side surfaces of the first bank layer, and a first inorganic encapsulation layer disposed on an upper surface of the first common electrode, the side surfaces of the first bank layer, and a lower surface and the side surfaces of the second bank layer, and spaced apart from the side surfaces of the second bank layer, wherein a maximum distance from an upper surface of the substrate to an upper surface of the second bank layer is greater than or equal to a maximum distance from the upper surface of the substrate to an upper surface of the first inorganic encapsulation layer.

The first inorganic encapsulation layer may include a first portion disposed on the upper surface of the first common electrode and a second portion spaced apart from the side surfaces of the second bank layer, and the first portion of the first inorganic encapsulation layer and the second portion of the first inorganic encapsulation layer may be connected to each other.

The display device may further include a first filler disposed in a groove defined by the first portion of the first inorganic encapsulation layer and the second portion of the first inorganic encapsulation layer.

The display device may further include an organic encapsulation layer disposed on the second bank layer and the first inorganic encapsulation layer, wherein the side surfaces of the second bank layer may contact the organic encapsulation layer.

The upper surface of the second bank layer may contact the organic encapsulation layer.

The first inorganic encapsulation layer may further include a third portion extending from the second portion and contacting a lower surface of the second bank layer and a fourth portion extending from the first portion and the third portion and contacting the side surfaces of the first bank layer, and a cavity surrounded by the first, second, third, and fourth portions of the first inorganic encapsulation layer.

An upper surface of the first filler may be aligned with the upper surface of the first inorganic encapsulation layer to form a flat surface.

The first filler may include spin-on-glass.

A refractive index of the first filler may be in a range of about 1.45 to about 1.60.

An upper surface of the first bank layer may not overlap the first inorganic encapsulation layer in a direction perpendicular to the substrate.

The first bank layer may include aluminum (Al), and the second bank layer may include titanium (Ti) or molybdenum (Mo).

The first inorganic encapsulation layer may include one or more of silicon nitrate (SiNₓ), silicon oxynitride (SiOₓN_{y}), and silicon oxide (SiOₓ).

According to another aspect of the disclosure, a display device may include a first pixel electrode disposed on a substrate, an inorganic insulating layer disposed on the substrate and exposing the first pixel electrode, a first light emitting layer disposed on the first pixel electrode, a first common electrode disposed on the first light emitting layer, a first bank layer disposed on the inorganic insulating layer, a second bank layer disposed on the first bank layer and including side surfaces protruding more than side surfaces of the first bank layer, a first inorganic encapsulation layer disposed on an upper surface of the first common electrode, the side surfaces of the first bank layer, and a lower surface and the side surfaces of the second bank layer, the first inorganic encapsulation layer spaced apart from the side surfaces of the second bank layer, and
an organic encapsulation layer disposed on the second bank layer and the first inorganic encapsulation layer, wherein the organic encapsulation layer contacts an upper surface and the side surfaces of the second bank layer, and an upper surface of the first bank layer may not overlap the first inorganic encapsulation layer in a direction perpendicular to the substrate.

The display device may further include a first filler, wherein the first inorganic encapsulation layer may include a first portion disposed on the upper surface of the first common electrode and a second portion spaced apart from the side surfaces of the second bank layer, the first portion of the first inorganic encapsulation layer and the second portion of the first inorganic encapsulation layer may be connected to each other, and the first filler may be disposed in a groove defined by the first portion of the first inorganic encapsulation layer and the second portion of the first inorganic encapsulation layer.

The entire upper surface of the second bank layer may contact the organic encapsulation layer.

According to another aspect of the disclosure, a method of fabricating a display device may include forming a plurality of pixel electrodes spaced apart from each other on a substrate, forming an inorganic insulating material layer on the plurality of pixel electrodes, forming a first bank material layer on the inorganic insulating material layer, and forming a second bank material layer on the first bank material layer, forming holes which expose the plurality of pixel electrodes by etching the first bank material layer and the second bank material layer and etching side surfaces of the first bank material layer exposed in the holes to expose a portion of a lower surface of the second bank material layer, forming a first light emitting layer on a first pixel electrode among the plurality of pixel electrodes and forming a first common electrode on the first light emitting layer, forming a first inorganic encapsulation layer on the first common electrode, coating a first filler on the first inorganic encapsulation layer, forming a mask pattern layer on the first inorganic encapsulation layer overlapping the first pixel electrode and etching the first inorganic encapsulation layer and the first filler not covered by the mask pattern layer by an etching process, and partially etching the first inorganic encapsulation layer and the first filler covered by the mask pattern layer.

In the forming of the first inorganic encapsulation layer on the first common electrode, the first inorganic encapsulation layer may be formed on an upper surface of the first common electrode, the side surfaces of the first bank material layer, and the lower surface and side surfaces of the second bank material layer, and the first inorganic encapsulation layer formed on the side surfaces of the second bank material layer may be bonded to the first inorganic encapsulation layer formed on the upper surface of the first common electrode.

In the forming of the mask pattern layer on the first inorganic encapsulation layer overlapping the first pixel electrode and the etching of the first inorganic encapsulation layer and the first filler not covered by the mask pattern layer by the etching process, an anisotropic dry etching process may be performed until the first inorganic encapsulation layer on the second bank material layer may be removed, and thus the first inorganic encapsulation layer and the first filler may remain on a second pixel electrode.

In the partially etching of the first inorganic encapsulation layer and the first filler covered by the mask pattern layer, the first inorganic encapsulation layer on the second pixel electrode, the first filler, the first common electrode and the first light emitting layer may be removed, the mask pattern layer may be removed, and the first inorganic encapsulation layer and the first filler may be etched such that upper surfaces of the first inorganic encapsulation layer and the first filler on the first pixel electrode may be aligned with an upper surface of the second bank material layer to form a flat surface.

The first inorganic encapsulation layer may include one or more of silicon nitrate (SiNₓ), silicon oxynitride (SiNₓN_{y}) and silicon oxide (SiNₓ), and the first filler may include spin-on-glass.

According to an embodiment, the lower inorganic encapsulation layer is aligned with or disposed below the upper surface of the second bank layer, thereby increasing the stability of the lower inorganic encapsulation layer.

It should be noted that effects of the disclosure are not limited to those described above and other effects of the disclosure will be apparent to those skilled in the art from the following descriptions.

### BRIEF DESCRIPTION OF THE DRAWINGS

These and/or other aspects will become apparent and more readily appreciated from the following description of the embodiments, taken in conjunction with the accompanying drawings in which:

FIG. 1 is a schematic perspective view of an electronic device according to an embodiment;

FIG. 2 is a schematic perspective view of a display device included in the electronic device according to an embodiment;

FIG. 3 is a schematic cross-sectional view of the display device of FIG. 2 as viewed from the side;

FIG. 4 is a schematic plan view of a display layer of a display device according to an embodiment;

FIG. 5 is a schematic plan view illustrating the arrangement of a second bank layer, a first inorganic encapsulation layer, an organic encapsulation layer, and fillers of the display device according to an embodiment;

FIG. 6 is a schematic cross-sectional view of a portion of the display device taken along line B-B′ of FIG. 5 according to an embodiment;

FIG. 7 is an enlarged schematic view of a first emission area, e.g., area A1 of FIG. 6;

FIG. 8 is a schematic cross-sectional view illustrating a case where a first inorganic encapsulation layer is disposed on an upper surface of the second bank layer; and

FIGS. 9, 10, 11, 12, 13, 14, 15, 16, and 17 are schematic cross-sectional views sequentially illustrating a process of fabricating a display device according to an embodiment.

### DETAILED DESCRIPTION OF THE EMBODIMENTS

In the following description, for the purposes of explanation, numerous specific details are set forth in order to provide a thorough understanding of various embodiments or implementations of the invention. As used herein “embodiments” and “implementations” are interchangeable words that are non-limiting examples of devices or methods disclosed herein. It is apparent, however, that various embodiments may be practiced without these specific details or with one or more equivalent arrangements. Here, various embodiments do not have to be exclusive nor limit the disclosure. For example, specific shapes, configurations, and characteristics of an embodiment may be used or implemented in another embodiment.

Unless otherwise specified, the illustrated embodiments are to be understood as providing features of the invention. Therefore, unless otherwise specified, the features, components, modules, layers, films, panels, regions, and/or aspects, etc. (hereinafter individually or collectively referred to as “elements”), of the various embodiments may be otherwise combined, separated, interchanged, and/or rearranged without departing from the invention.

The use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified. Further, in the accompanying drawings, the size and relative sizes of elements may be exaggerated for clarity and/or descriptive purposes. When an embodiment may be implemented differently, a specific process order may be performed differently from the described order. For example, two consecutively described processes may be performed substantially at the same time or performed in an order opposite to the described order. Also, like reference numerals denote like elements.

When an element, such as a layer, is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements. Further, the DR1-axis, the DR2-axis, and the DR3-axis are not limited to three axes of a rectangular coordinate system, such as the X, Y, and Z-axes, and may be interpreted in a broader sense. For example, the DR1-axis, the DR2-axis, and the DR3-axis may be perpendicular to one another, or may represent different directions that are not perpendicular to one another. Further, the X-axis, the Y-axis, and the Z-axis are not limited to three axes of a rectangular coordinate system, such as the x, y, and z axes, and may be interpreted in a broader sense. For example, the X-axis, the Y-axis, and the Z-axis may be perpendicular to one another, or may represent different directions that are not perpendicular to one another. For the purposes of this disclosure, “at least one of A and B” may be construed as understood to mean A only, B only, or any combination of A and B. Also, “at least one of X, Y, and Z” and “at least one selected from the group consisting of X, Y, and Z” may be construed as X only, Y only, Z only, or any combination of two or more of X, Y, and Z. As used herein, the term “and/or” includes any and all combinations of one or more of the associated listed items.

Although the terms “first,” “second,” etc. may be used herein to describe various types of elements, these elements should not be limited by these terms. These terms are used to distinguish one element from another element. Thus, a first element discussed below could be termed a second element without departing from the teachings of the disclosure.

Spatially relative terms, such as “beneath,” “below,” “under,” “lower,” “above,” “upper,” “over,” “higher,” “side” (e.g., as in “sidewall”), and the like, may be used herein for descriptive purposes, and, thereby, to describe one elements relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the term “below” can encompass both an orientation of above and below. Furthermore, the apparatus may be otherwise oriented (e.g., rotated 90 degrees or at other orientations), and, as such, the spatially relative descriptors used herein interpreted accordingly.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof. It is also noted that, as used herein, the terms “substantially,” “about,” and other similar terms, are used as terms of approximation and not as terms of degree, and, as such, are utilized to account for inherent deviations in measured, calculated, and/or provided values that would be recognized by one of ordinary skill in the art.

Various embodiments are described herein with reference to sectional and/or exploded illustrations that are schematic illustrations of embodiments and/or intermediate structures. As such, variations from the shapes of the illustrations as a result, for example, of manufacturing techniques and/or tolerances, are to be expected. Thus, embodiments disclosed herein should not necessarily be construed as limited to the particular illustrated shapes of regions, but are to include deviations in shapes that result from, for instance, manufacturing. In this manner, regions illustrated in the drawings may be schematic in nature and the shapes of these regions may not reflect actual shapes of regions of a device and, as such, are not necessarily intended to be limiting.

As customary in the field, some embodiments are described and illustrated in the accompanying drawings in terms of functional blocks, units, and/or modules. Those skilled in the art will appreciate that these blocks, units, and/or modules are physically implemented by electronic (or optical) circuits, such as logic circuits, discrete components, microprocessors, hard-wired circuits, memory elements, wiring connections, and the like, which may be formed using semiconductor-based fabrication techniques or other manufacturing technologies. In the case of the blocks, units, and/or modules being implemented by microprocessors or other similar hardware, they may be programmed and controlled using software (e.g., microcode) to perform various functions discussed herein and may optionally be driven by firmware and/or software. It is also contemplated that each block, unit, and/or module may be implemented by dedicated hardware, or as a combination of dedicated hardware to perform some functions and a processor (e.g., one or more programmed microprocessors and associated circuitry) to perform other functions. Also, each block, unit, and/or module of some embodiments may be physically separated into two or more interacting and discrete blocks, units, and/or modules without departing from the scope of the invention. Further, the blocks, units, and/or modules of some embodiments may be physically combined into more complex blocks, units, and/or modules without departing from the scope of the invention. Hereinafter, embodiments will be described with reference to the accompanying drawings.

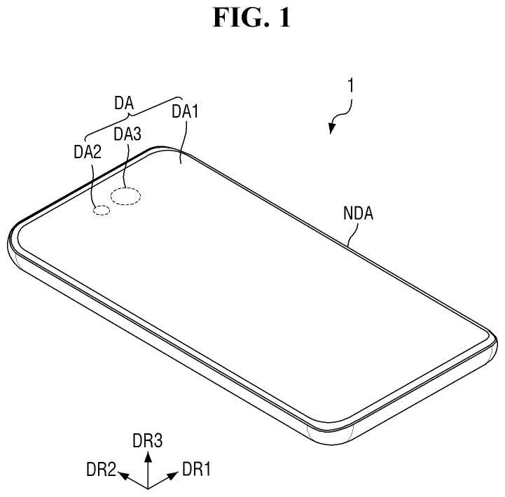

FIG. 1 is a schematic plan view of an electronic device according to an embodiment.

Referring to FIG. 1, the electronic device 1 may display moving images or still images. The electronic device 1 may refer to any electronic device that includes a display screen. Examples of the electronic device 1 may include a television, a notebook computer, a monitor, a billboard, an Internet of things (IoT) device, a mobile phone, a smartphone, a tablet personal computer (PC), an electronic watch, a smart watch, a watch phone, a head-mounted display, a mobile communication terminal, an electronic notebook, an electronic book, a portable multimedia player (PMP), a navigation device, a game console, a digital camera and a camcorder, all of which include a display screen.

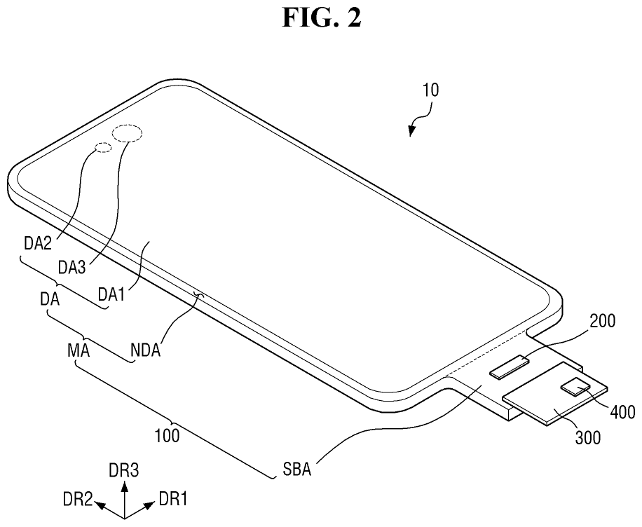

The electronic, device 1 may include a display device 10 (see FIG. 2) that includes a display screen. Examples of the display device 10 may include an inorganic light emitting diode display device, an organic light emitting display device, a quantum dot light emitting display device, a plasma display panel, and a field emission display device. A case where an organic light emitting diode display device is applied as an example of the display device 10 will be described below, but embodiments are not limited to this case, and other display devices may also be applied thereto.

The shape of the electronic device 1 may be-variously modified. For example, the electronic device 1 may have various shapes such as a horizontally long rectangle, a vertically long rectangle, a square, a quadrilateral with rounded corners (e.g., vertices), other polygons, and a circle, The shape of a display area DA of the electronic device 1 may also be similar to the overall shape of the electronic device 1. In FIG. 1, the electronic device 1 may be shaped like a rectangle that is long in a second direction DR2.

The electronic device 1 may include the display area DA and a non-display area NDA. The display area DA may be an area where an image is displayed, and the non-display area NDA may be an area when no image is displayed. The display area DA may also be referred to as an active area, and the non-display area NDA may also be referred to as an inactive area. The display area DA may generally occupy a center area of the electronic device 1.

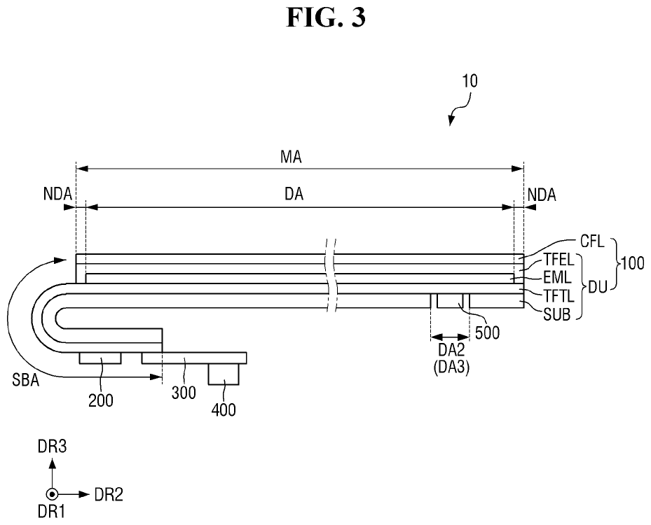

The display area DA may include a first display area DA1, a second display area DA2, and a third display area DA3. The second display area DA2 and the third display area DA3 may be areas where components for adding various functions to the electronic device 1 are disposed. The second display area DA2 and the third display area DA3 may be component areas. The components may be an optical device 500 illustrated in FIG. 3.

FIG. 2 is a schematic perspective view of the display device 10 included in the electronic device 1 according to an embodiment.

Referring to FIG. 2, the electronic device 1 according to an embodiment may include the display device 10. The display device 10 may include a screen that is displayed by the electronic device 1. The display device 10 may have a planar shape similar to that of the electronic device 1. For example, the display device 10 may be shaped like a rectangle having short sides in a first direction DR1 and long sides in the second direction DR2. Each corner where a short side extending in the first direction DR1 meets a long side extending in the second direction DR2 may be rounded at a curvature. However, embodiments are not limited thereto, and each corner may also be right-angled. The planar shape of the display device 10 is not limited to a quadrilateral shape but may also be another polygonal shape, a circular shape, or an oval shape.

The display device 10 may include a display panel 100, a display driver 200, a circuit board 300, and a touch driver 400.

The display panel 100 may include a main area MA and a sub-area SBA.

The main area MA may include a display area DA including pixels that display an image and a non-display area NDA disposed around the display area DA. The display area DA may include a first display area DA1, a second display area DA2, and a third display area DA3. The display area DA may emit light from emission areas or opening areas. For example, the display panel 100 may include pixel circuits including switching elements, a pixel defining layer defining the emission areas or the opening areas, and self-light emitting elements.

For example, the self-light emitting elements may include at least one of an organic light emitting diode including an organic light emitting layer, a quantum dot light emitting diode including a quantum dot light emitting layer, an inorganic light emitting diode including an inorganic semiconductor, and a micro-light emitting diode. However, embodiments are not limited thereto.

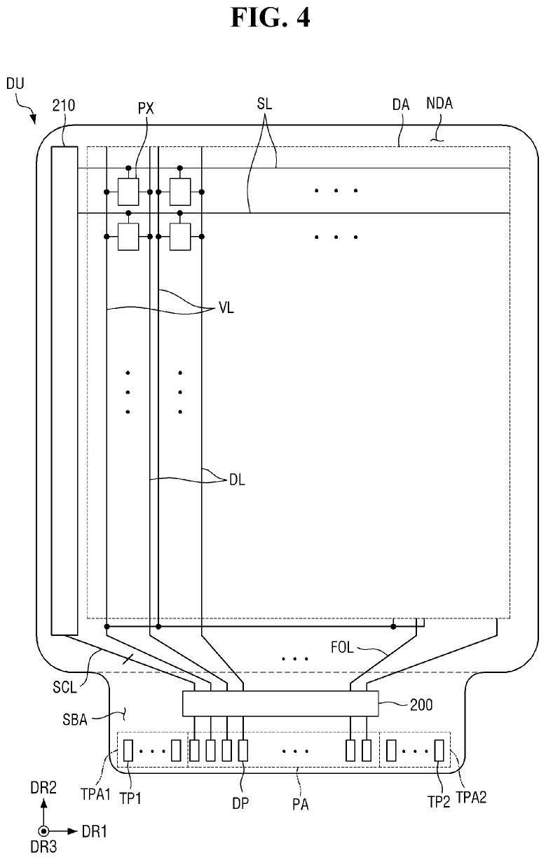

The non-display area NDA may be an area outside the display area DA. The non-display area NDA may be defined as an edge area of the main area MA of the display panel 100. The non-display area NDA may include a scan driver 210 (see FIG. 4) supplying scan signals to scan lines and fan-out lines FOL (see FIG. 4) connecting the display driver 200 and the display area DA.

The sub-area SBA may be an area extending from a side of the main area MA. The sub-area SBA may include a flexible material that is bendable, foldable, rollable, etc. For example, in case that the sub-area SBA is bent, the sub-area SBA may be overlapped by the main area MA in a thickness direction (e.g., third direction DR3). The sub-area SBA may include the display driver 200 and a pad unit connected to the circuit board 300. In an embodiment, the sub-area SBA may be omitted, and the display driver 200 and the pad unit may be disposed in the non-display area NDA.

The display driver 200 may output signals and voltages for driving the display panel 100. The display driver 200 may supply data voltages to data lines. The display driver 200 may supply a power supply voltage to a power line and supply a scan control signal to the scan driver. The display driver 200 may be formed as an integrated circuit and mounted on the display panel 100 by a chip on glass (COG) method, a chip on plastic (COP) method, or an ultrasonic bonding method. For example, the display driver 200 may be disposed in the sub-area SBA and may be overlapped by the main area MA in the thickness direction (e.g., third direction DR3) by the bending of the sub-area SBA. For another example, the display driver 200 may be mounted on the circuit board 300.

The circuit board 300 may be attached onto the pad unit of the display panel 100 by using an anisotropic conductive film. Lead lines of the circuit board 300 may be electrically connected to the pad unit of the display panel 100. The circuit board 300 may be a flexible printed circuit board, a printed circuit board, or a flexible film such as a chip on film.

The touch driver 400 may be mounted on the circuit board 300. The touch driver 400 may be electrically connected to a touch sensing unit of the display panel 100. The touch driver 400 may supply a touch driving signal to touch electrodes of the touch sensing unit and sense a change in capacitance between the touch electrodes. For example, the touch driving signal may be a pulse signal having a frequency. The touch driver 400 may calculate whether a touch input has been made and coordinates of the touch input based on a change in capacitance between the touch electrodes. The touch driver 400 may be formed as an integrated circuit.

FIG. 3 is a schematic cross-sectional view of the display device 10 of FIG. 2 as viewed from the side.

Referring to FIG. 3, the display panel 100 may include a display layer DU and a color filter layer CFL. The display layer DU may include a substrate SUB, a thin-film transistor layer TFTL, a light emitting element layer EML, and a thin-film encapsulation layer TFEL.

The substrate SUB may be a base substrate or a base member. The substrate SUB may be a flexible substrate that is bendable, foldable, rollable, etc. For example, the substrate SUB may include polymer resin such as polyimide (PI). However, embodiments are not limited thereto. In an embodiment, the substrate SUB may include a glass material or a metal material.

The thin-film transistor layer TFTL may be disposed on the substrate SUB. The thin-film transistor layer TFTL may include thin-film transistors included in pixel circuits of pixels. The thin-film transistor layer TFTL may further include scan lines, data lines, power lines, scan control lines, fan-out lines connecting the display driver 200 and thee data lines, and lead lines connecting the display driver 200 and the pad unit. Each of the thin-film transistors may include a semiconductor region, a source electrode, a drain electrode, and a gate electrode. For example, in case that the scan driver is formed on a side of the non-display area NDA of the display panel 100, the scan driver may include thin-film transistors.

The thin-film transistor layer TFTL may be disposed in the display area DA, the non-display area NDA, and the sub-area SBA. The thin-film transistors of the pixels, the scan lines, the data lines, and the power lines of the thin-film transistor layer TFTL may be disposed in the display area DA. The scan control lines and the fan-out lines of the thin-film transistor layer TFTL may be disposed in the non-display area NDA, The lead lines of the thin-film transistor layer TFTL may be disposed in the sub-area SBA.

The light emitting element layer EML may be disposed on the thin-film transistor layer TFTL. The light emitting element layer EML may include light emitting elements, each including a first electrode, a second electrode and a light emitting layer to emit light, and a pixel defining layer defining the pixels. The light emitting elements of the light emitting element layer EML may be disposed in the display area DA.

In an embodiment, the light emitting layer may be an organic light emitting layer including an organic material. The light emitting layer may include a hole transporting layer, an organic light emitting layer, and an electron transporting layer. In case that the first electrode receives a voltage through a thin-film transistor of the thin-film transistor layer TFTL and the second electrode receives a cathode voltage, holes and electrons may move to the organic light emitting layer through the hole transporting layer and the electron transporting layer, respectively, and may be combined with each other in the organic light emitting layer to emit light.

In an embodiment, each of the light emitting elements may include a quantum dot light emitting diode including a quantum dot light emitting layer, an inorganic light emitting diode including an inorganic semiconductor, or a micro-light emitting diode.

The thin-film encapsulation layer TFEL may cover upper and side surfaces of the light emitting element layer EML and may protect the light emitting element layer EML. The thin-film encapsulation layer TFEL may include at least one inorganic layer and at least one organic layer to encapsulate the light emitting element layer EML.

A touch sensing layer may be positioned on the display layer DU. The touch sensing layer may obtain coordinates of a touch input point by using a capacitance method. In the capacitance method, coordinate information of a touched point may be obtained by using a self-capacitance method or a mutual capacitance method, but embodiments are not limited thereto.

The color filter layer CFL may be disposed on the thin-film encapsulation layer TFEL. The color filter layer CFL may include color filters corresponding to emission areas, respectively. Each of the color filters may selectively transmit light of a specific wavelength and block or absorb light of other wavelengths. The color filter layer CFL may absorb a portion of light transmitting from the outside of the display device 10 to reduce reflected light due to the external light. Therefore, the color filter layer CFL may prevent color distortion due to reflection of the external light.

Since the color filter layer CFL is directly disposed on the thin-film encapsulation layer TFEL, the display device 10 may not require a separate substrate for the color filter layer CFL. Therefore, a thickness of the display device 10 may be relatively small.

In some embodiments, the display device 10 may further include the optical device 500. The optical device 500 may be disposed in the second display area DA2 or the third display area DA3. The optical device 500 may emit or receive light in an infrared light band, an ultraviolet light band, or a visible light band. For example, the optical device 500 may be an optical sensor that senses light incident on the display device 10, such as a proximity sensor, an illuminance sensor, a camera sensor, a fingerprint sensor or an image sensor.

FIG. 4 is a schematic plan view of a display layer DU of a display device 10 according to an embodiment.

Referring to FIG. 4, the display layer DU may include a display area DA and a non-display area NDA.

The display area DA may be disposed in a center area of a display panel 100. In the display area DA, pixels PX, scan lines SL, data lines DL, and power lines VL may be disposed. Each of the pixels PX may be defined as a minimum unit that emits light.

The scan lines SL may supply scan signals received from a scan driver 210 to the pixels PX, The scan lines SL may extend in the first direction DR1 and may be spaced apart from each other in the second direction DR2 intersecting the first direction DR1.

The data lines DL may supply data voltages received from a display driver 200 to the pixels PX. The data lines DL may extend in the second direction DR2 and may be spaced apart from each other in the first direction DR1.

The power lines VL may supply a power supply voltage received from the display driver 200 to the pixels PX. For example, the power supply voltage may be at least one of a driving voltage, an initialization voltage, a reference voltage, and a low-potential voltage. The power lines VL may extend in the second direction DR2 and may be spaced apart from each other in the first direction DR1.

The non-display area NDA may surround the display area DA. In the non-display area NDA, the scan driver 210, fan-out lines FOL, and scan control lines SOL may be disposed. The scan driver 210 may generate scan signals based on a scan control signal and sequentially supply the scan signals to the scan lines SL according to a set order.

The fan-out lines FOL may extend from the display driver 200 to the display area DA. The fan-out lines FOL may supply data voltages received from the display driver 200 to the data lines DL.

The scan control lines SCL may extend from the display driver 200 to the scan driver 210. The scan control lines SCL may supply a scan control signal received from the display driver 200 to the scan driver 210.

A sub-area SBA may include the display driver 200, a pad area PA, and first and second touch pad areas TPA1 and TPA2.

The display driver 200 may output signals and voltages for driving the display panel 100 to the fan-out lines FOL. The display driver 200 may supply data voltages to the data lines DL through the fan-out lines FOL. The data voltages may be supplied to the pixels PX and may control luminances of the pixels PX. The display driver 200 may supply a scan control signal to the scan driver 210 through the scan control lines SCL.

The pad area PA, the first touch pad area TPA1, and the second touch pad area TPA2 may be disposed at an edge portion of the sub-area SBA. The pad area PA, the first touch pad area TPA1, and the second touch pad area TPA2 may be electrically connected to a circuit board 300 by using a material such as an anisotropic conductive film or self-assembly anisotropic conductive paste (SAP).

The pad area PA may include display pad units DP. The display pad units DP may be connected to a graphics system through the circuit board 300. The display pad units DP may be connected to the circuit board 300 to receive digital video data and may supply the digital video data to the display driver 200.

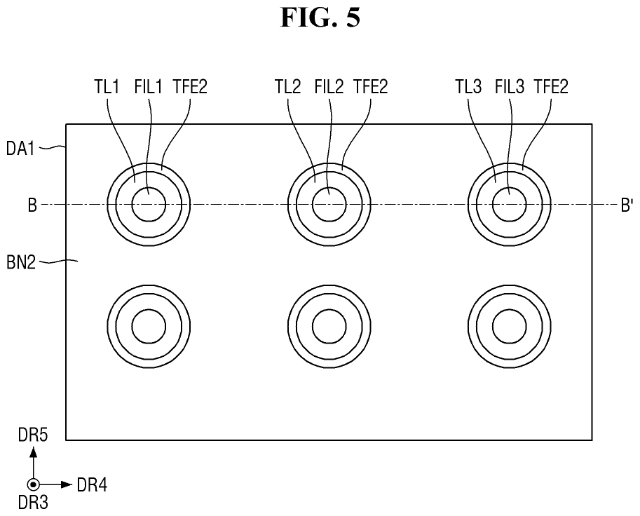

FIG. 5 is a schematic plan view of a portion of the display device 10 according to an embodiment. FIG. 5 is a schematic plan view illustrating the arrangement of a second bank layer BN2, lower inorganic encapsulation layers TFE1 (e.g., TL1, TL2, and TL3), an organic encapsulation layer TFE2, and fillers FIL1, FIL2, and FIL3 in the display area DA of the display device 10.

Referring to FIG. 5, the second bank layer BN2 may cover the display area DA but may partially expose the display area DA. A filler FIL1, FIL2, or FIL3 may be disposed in a center of an area exposed without being covered by the second bank layer BN2, a lower inorganic encapsulation layer TL1, TL2 or TL3 may be disposed around the filler FIL1, FIL2 or FIL3, and the organic encapsulation layer TFE2 may be disposed around the lower inorganic encapsulation layer TL1, TL2 or TL3. In FIG. 5, the area exposed without being covered by the second bank layer BN2 may be circular. However, the area may also have a polygonal shape such as a triangle or a quadrilateral.

The area exposed without being covered by the second bank layer BN2 may be provided in plural, and each of the areas may emit light of one color. In FIG. 5, an area including a first filler FIL1, a first inorganic encapsulation layer TL1 and the organic encapsulation layer TFE2 may emit red light (or first color light), an area including a second filler FIL2, a second inorganic encapsulation layer TL2 and the organic encapsulation layer TFE2 may emit green light (or second color light), and an area including a third filler FIL3, a third inorganic encapsulation layer TL3 and the organic encapsulation layer TFE2 may emit blue light (or third color light). However, embodiments are not limited thereto.

The areas exposed without being covered by the second bank layer BN2 may be spaced apart from each other in a fourth direction DR4 and may also be spaced apart from each other in a fifth direction DR5. The fourth direction DR4 is an arbitrary direction in a plane including the first direction DR1 and the second direction DR2, and the fifth direction DR5 is a direction perpendicular to the fourth direction DR4. The areas exposed without being covered by the second bank layer BN2 may not be arranged as in FIG. 5 but may also be arranged in a pentile type.

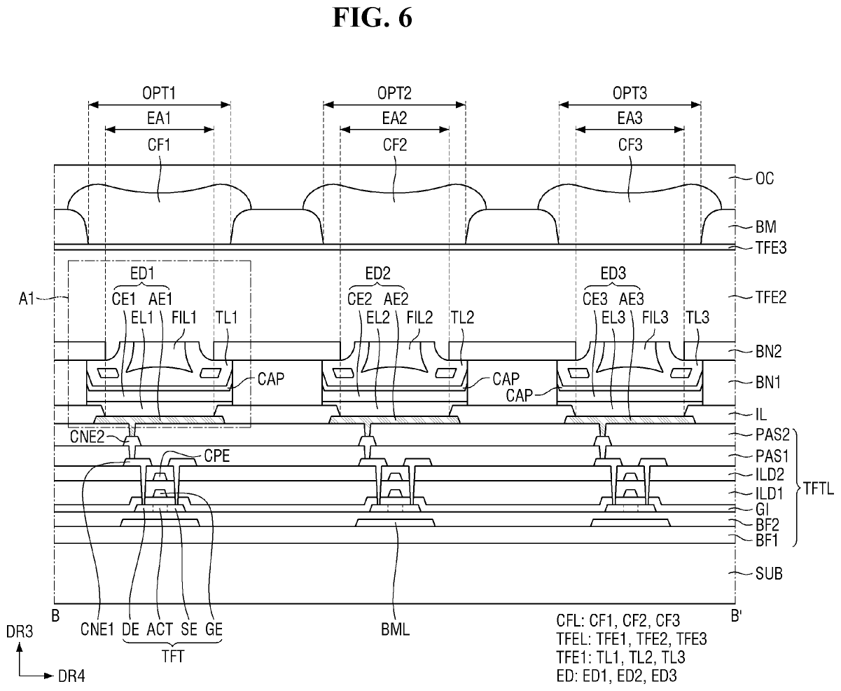

FIG. 6 is a schematic cross-sectional view of a portion of the display device 10 according to an embodiment. FIG. 6 is a schematic cross-sectional view taken along line B-B′ of FIG. 5, also illustrating an upper inorganic encapsulation layer TFE3, color filters CF1, CF2, and CF3, a light blocking layer BM, and an overcoat layer OC disposed on the plan view of FIG. 5. FIG. 6 illustrates cross-sections of a substrate SUB, a thin-film transistor layer TFTL, a light emitting element layer EML, a thin-film encapsulation layer TFEL, and a color filter layer CFL of the display layer DU.

Referring to FIG. 6, the display panel 100 of the display device 10 may include the display layer DU and the color filter layer CFL. The display layer DU may include the substrate SUB, the thin-film transistor layer TFTL, the light emitting element layer EML, and the thin-film encapsulation layer TFEL. The display panel 100 may include the light blocking layer BM disposed on the thin-film encapsulation layer TFEL, and the color filters CF1, CF2, and CF3 of the color filter layer CFL may be disposed on the light blocking layer BM.

The substrate SUB may be a base substrate or a base member. The substrate SUB may be a flexible substrate that is bendable, foldable, rollable, etc. For example, the substrate SUB may include polymer resin such as polyimide PI. However, embodiments are not limited thereto. For another example, the substrate SUB may include a glass material or a metal material.

The thin-film transistor layer TFTL may include a first buffer layer BF1, bottom metal layers BML, a second buffer layer BF2, thin-film transistors TFT, a gate insulating layer GI, a first interlayer insulating layer ILD1, capacitor electrodes CPE, a second interlayer insulating layer ILD2, first connection electrodes CNE1, a first passivation layer PAS1, second connection electrodes CNE2, and a second passivation layer PAS2.

The first buffer layer BF1 may be disposed on the substrate SUB. The first buffer layer BF1 may include an inorganic layer that prevents penetration (or permeation) of air or moisture. For example, the first buffer layer BF1 may include inorganic layers stacked alternately.

The bottom metal layers BML may be disposed on the first buffer layer BF1. For example, each of the bottom metal layers BML, may be a single layer or a multilayer made of any one or more of molybdenum (Mo), aluminum (Al), chromium (Cr), gold (Au), titanium (Ti), nickel (Ni), neodymium (Nd), copper (Cu), and alloys thereof.

The second buffer layer BF2 may cover the first buffer layer BF1 and the bottom metal layers BML. The second buffer layer BF2 may include an inorganic layer that prevents penetration (or permeation) of air or moisture. For example, the second buffer layer BF2 may include inorganic, layers stacked alternately.

The thin-film transistors TFT may be disposed on the second buffer layer BF2 and may constitute respective pixel circuits of pixels. For example, each of the thin-film transistors TFT may be a driving transistor or a switching transistor of a pixel circuit. Each of the thin-film transistors TFT may include a semiconductor layer ACT, a source electrode SE, a drain electrode DE, and a gate electrode GE.

The semiconductor layer ACT may be disposed on the second butler layer BF2. The semiconductor layer ACT may overlap a bottom metal layer BML and the gate electrode GE in the thickness direction DR3 and may be insulated from the gate electrode GE by the gate insulating layer GI. In portions of the semiconductor layer ACT, the material of the semiconductor layer ACT may be made conductive to form the source electrode SE and the drain electrode DE.

The gate electrode GE may be disposed on the gate insulating layer GI. The gate electrode GE may overlap the semiconductor layer ACT in the thickness direction DR3 with the gate insulating layer GI interposed between the gate electrode GE and the semiconductor layer ACT.

The gate insulating layer GI may be disposed on the semiconductor layers ACT, For example, the gate insulating layer GI may cover the semiconductor layers ACT and the second buffer layer BF2 and may insulate the semiconductor layers ACT from the gate electrodes GE. The gate insulating layer GI may include contact holes through which the first connection electrodes CNE1 pass.

The first interlayer insulating layer ILD1 may cover the gate electrodes GE and the gate insulating layer GI. The first interlayer insulating layer ILD1 may include contact holes through which the first connection electrodes CNE1 pass. The contact holes of the first interlayer insulating layer ILD1 may be connected to the contact holes of the gate insulating layer GI and contact holes of the second interlayer insulating layer ILD2.

The capacitor electrodes CPE may be disposed on the first interlayer insulating layer ILD1. The capacitor electrodes CPE may overlap the gate electrodes GE in the thickness direction DR3. The capacitor electrodes CPE and the gate electrodes GE may form capacitances.

The second interlayer insulating layer may cover the capacitor electrodes CPE and the first interlayer insulating layer ILD1. The second interlayer insulating layer ILD2 may include the contact holes through which the first connection electrodes CNE1 pass. The contact holes of the second interlayer insulating layer IL2 may be connected to the contact holes of the first interlayer insulating layer ILD1 and the contact holes of the gate insulating layer GI.

The first connection electrodes CNE1 may be disposed on the second interlayer insulating layer ILD2. The first connection electrodes CNE1 may connect (e.g., electrically connect) the drain electrodes DE of the thin-film transistors TFT to the second connection electrodes CNE2. The first connection electrodes CNE1 may be inserted into the contact holes formed in the second interlayer insulating layer ILD2, the first interlayer insulating layer ILD1 and the gate insulating layer GI to contact the drain electrodes DE of the thin-film transistors TFT.

The first passivation layer PAS1 may cover the first connection electrodes CNET and the second interlayer insulating layer ILD2. The first passivation layer PAS1 may protect the thin-film transistors TFT. The first passivation layer PAS1 may include contact holes through which the second connection electrodes CNE2 pass.

The second connection electrodes CNE2 may be disposed on the first passivation layer PAS1. The second connection electrodes CNE2 may connect (e.g., electrically connect) the first connection electrodes CNET to pixel electrodes AE1, AE2, and AE3 of light emitting elements ED. The second connection electrodes CNE2 may be inserted into the contact holes formed in the first passivation layer PAS1 to contact the first connection electrodes CNE1.

The second passivation layer PAS2 may cover the second connection electrodes CNE2 and the first passivation layer PAS1. The second passivation layer PAS2 may include contact holes through which the pixel electrodes AE1, AE2, and AE3 of the light emitting elements ED pass.

The light emitting element layer EML may be disposed on the thin-film transistor layer TFTL. The light emitting element layer EML may include the light emitting elements ED, an inorganic insulating layer IL, capping layers CAP, and a bank structure BNS. Each of the light emitting elements ED may include the pixel electrode AE1, AE2 or AE3, a light emitting layer EL1, EL2 or EL3, and a common electrode CE1, CE2 or CE3.

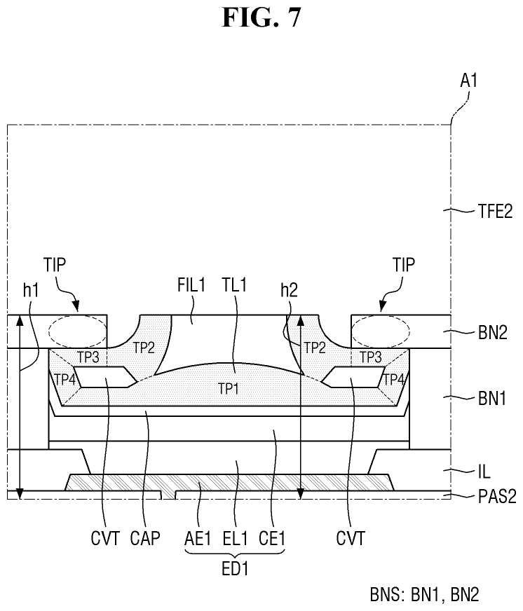

FIG. 7 is an enlarged schematic view of a first emission area EA1, e.g., area A1 of FIG. 6.

Referring to FIG. 7 in addition to FIG. 6, the display device 10 may include emission areas EA1, EA2, and EA3 disposed in the display area DA. The emission areas EA1, EA2, and EA3 may include areas where light is emitted from the light emitting elements ED1, ED2, and ED3 and travels (or transmits) to the color filter layer CFL in the third direction DR3. The emission areas EA1, EA2, and EA3 may include the first emission area EA1, a second emission area EA2, and a third emission area EA3 that emit light of different colors. The first, second, and third emission areas EA1, EA2, and EA3 may emit red light, green light and blue light, respectively, and the color of light emitted from each of the emission areas EA1, EA2, and EA3 may vary according to the type of light emitting element ED disposed in the light emitting element layer EML. In an embodiment, the first emission area EA1 in which a first pixel electrode AE1, a first light emitting layer EL1 and a first common electrode CE1 are sequentially stacked may emit red light (or first color light), the second emission area EA2 in which a second pixel electrode AE2, a second light emitting layer EL2 and a second common electrode CE2 are sequentially stacked may emit green light (or second color light), and the third emission area EA3 in which a third pixel electrode AE3, a third light emitting layer EL3 and a third common electrode CE3 are sequentially stacked may emit blue light (or third color light). However, embodiments are not limited thereto.

Openings formed in the bank structure BNS of the light emitting element layer EML are defined along the boundary of the bank structure BNS. A first bank layer BN1 and the second bank layer BN2 of the bank structure BNS may surround the emission areas EA1, EA2, and EA3. The openings may include the first, second, and third emission areas EA1, EA2, and EA3.

In an embodiment, the first, second, and third emission areas EA1, EA2, and EA3 may have the same area (or same size). For example, in the display device 10, the first emission area EA1, the second emission area EA2, and the third emission area EA3 may have the same size (e.g., the same area, the same diameter, or the same width). However, embodiments are not limited thereto. In the display device 10, the first, second, and third emission areas EA1, EA2, and EA3 may also have different areas (or different sizes). For example, the area of the second emission area EA2 may be larger than the area of the first emission area EA1 and the area of the third emission area EA3, and the area of the third emission area EA3 may be larger than the area of the first emission area EA1. The intensity of light emitted from each of the emission areas EA1, EA2, and EA3 may vary according to the area of the emission area EA1, EA2 or and EA3, and the color of a screen displayed on the display device 10 or the electronic device 1 may be controlled by adjusting the areas of the emission areas EA1, EA2, and EA3. In the embodiment of FIG. 6, the emission areas EA1, EA2, and EA3 have the same area. However, embodiments are not limited thereto.

In the display device 10, one first emission area EA1, one second emission area EA2, and one third emission area EA3 adjacent to each other may form a pixel group (e.g., single pixel group). The single pixel group may include the emission areas EA1, EA2, and EA3 emitting light of different colors to express a white gray level. However, embodiments are not limited thereto, and the combination of the emission areas EA1, EA2, and EA3 forming a pixel group (e.g., single pixel group) may be variously modified according to the arrangement of the emission areas EA1, EA2, and EA3 and the colors of light emitted from the emission areas EA1, EA2, and EA3.

The display device 10 may include light emitting elements ED1, ED2, and ED3 disposed in different emission areas EA1, EA2, and EA3. The light emitting elements ED1, ED2, and ED3 may include a first light emitting element ED1 disposed in the first emission area EA1, a second light emitting element ED2 disposed in the second emission area EA2, and a third light emitting element ED3 disposed in the third emission area EA3. The light emitting elements ED1, ED2, and ED3 may include the pixel electrodes AE1, AE2, and AE3, the light emitting layers EL1, EL2, and EL3, and the common electrodes CE1, CE2, and CE3, respectively. The light emitting elements ED1, ED2, and ED3 disposed in different emission areas EA1, EA2, and EA3 may emit light of different colors according to the materials of the light emitting layers EL1, EL2, and EL3. For example, the first light emitting element ED1 disposed in the first emission area EA1 may emit red light (or first color light) having a peak wavelength of about 610 nm to about 650 nm, the second light emitting element ED2 disposed in the second emission area EA2 may emit green light (or second color light) having a peak wavelength of about 510 nm to about 550 nm, and the third light emitting element ED3 disposed in the third emission area EA3 may emit blue light (or third color light) having a peak wavelength of about 440 nm to about 480 nm. The first, second, and third emission areas EA1, EA2, and EA3 forming a pixel (e.g., single pixel) may include the light emitting elements ED1, ED2, and ED3 emitting light of different colors to express a white gray level.

The pixel electrodes AE1, AE2, and AE3 may be disposed on the second passivation layer PAS2. The pixel electrodes AE1, AE2, and AE3 may be disposed in the emission areas EA1, EA2, and EA3, respectively. The pixel electrodes AE1, AE2, and AE3 may include the first pixel electrode AE1 disposed in the first emission area EA1, the second pixel electrode AE2 disposed in the second emission area EA2, and the third pixel electrode AE3 disposed in the third emission area EA3. The first pixel electrode AE1, the second pixel electrode AE2, and the third pixel electrode AE3 may be spaced apart from each other on the second passivation layer PAS2. In FIG. 6, a case where the first, second, and third pixel electrodes AE1, AE2, and AE3 are spaced apart from each other in the fourth direction DR4 is illustrated as an example. The pixel electrodes AE1, AE2, and AE3 may be disposed in different emission areas EA1, EA2, and EA3 to form the light emitting elements ED1, ED2, and ED3 emitting light of different colors.

The pixel electrodes AE1, AE2, and AE3 may be connected (e.g., electrically connected) to the drain electrodes DE of the thin-film transistors TFT through the first and second connection electrodes CNE1 and CNE2. The first, second, and third pixel electrodes AE1, AE2, and AE3 may be insulated from each other by the inorganic insulating layer IL. For example, the first, second, and third pixel electrodes AE1, AE2, and AE3 may include at least one of silver (Ag), copper (Cu), aluminum (Al), nickel (Ni), and lanthanum (La). For another example, the first, second, and third pixel electrodes AE1, AE2, and AE3 may include a material such as indium tin oxide (ITO), indium zinc oxide (IZO), or indium tin zinc oxide (ITZO). For another example, the first, second, and third pixel electrodes AE1, AE2, and AE3 may have a stacked structure of ITO/Ag/ITO, ITO/Ag/IZO, or ITO/Ag/ITZO/IZO.

The inorganic insulating layer IL may be disposed on the second passivation layer PAS2 and the pixel electrodes AE1, AE2, and AE3. The inorganic insulating layer ISL may cover side surfaces of the first, second, and third pixel electrodes AE1, AE2, and AE3 and edge portions of upper surfaces of the first, second, and third pixel electrodes AE1, AE2, and AE3. The inorganic insulating layer IL may be disposed on the entire surface of the second passivation layer PAS2 but may partially expose the upper surfaces of the pixel electrodes AE1, AE2, and AE3 to define the emission areas EA1, EA2, and EA3. For example, the inorganic insulating layer ISL may expose the first pixel electrode AE1 in the first emission area EA1, and the first light emitting layer EL1 may be disposed (e.g., directly disposed) on the first pixel electrode AE1. The inorganic insulating layer ISL may include an inorganic insulating material. The inorganic insulating layer IL may include at least one of a silicon nitride layer, a silicon oxynitride layer, a silicon oxide layer, a titanium oxide layer, an aluminum oxide layer, tantalum oxide, hafnium oxide, zinc oxide, and an amorphous silicon layer. However, embodiments are not limited thereto.

The light emitting layers EL1, EL2, and EL3 may be disposed on the pixel electrodes AE1, AE2, and AE3. The light emitting layers EL1, EL2, and EL3 may be organic light emitting layers made of an organic material and may be formed on the pixel electrodes AE1, AE2, and AE3 by a deposition process. In case that the thin-film transistors TFT apply a voltage to the pixel electrodes AE1, AE2, and AE3 of the light emitting elements ED1, ED2, and ED3 and in case that the common electrodes CE1, CE2, and CE3 of the light emitting elements ED1, ED2, and ED3 receive a common voltage or a cathode voltage, holes and electrons may move to the light emitting layers EL1, EL2, and EL3 through a hole transporting layer and an electron transporting layer, respectively. Then, the holes and electrons may be combined with each other in the light emitting layers EL1, EL2, and EL3 to emit light.

The light emitting layers EL1, EL2, and EL3 may include the first light emitting layer EL1, the second light emitting layer EL2, and the third light emitting layer EL3 disposed in different emission areas EA1, EA2, and EA3. The first light emitting layer EL1 may be disposed on the first pixel electrode AE1 in the first emission area EA1, the second light emitting layer EL2 may be disposed on the second pixel electrode AE2 in the second emission area EA2, and the third light emitting layer EL3 may be disposed on the third pixel electrode AE3 in the third emission area EA3. The first, second, and third light emitting layers EL1, EL2, and EL3 may be light emitting layers of the first, second, and third light emitting elements ED1, ED2, and ED3, respectively. The first light emitting layer EL1 may be a light emitting layer emitting red light of a first color, the second light emitting layer EL2 may be a light emitting layer emitting green light of a second color, and the third light emitting layer EL3 may be a light emitting layer emitting blue light of a third color.

The common electrodes CE1, CE2, and CE3 may be disposed on the light emitting layers EL1, EL2, and EL3. The common electrodes CE1, CE2, and CE3 may include a transparent conductive material to allow light generated by the light emitting layers EL1, EL2, and EL3 to pass therethrough. The common electrodes CE1, CE2, and CE3 may receive a common voltage or a low potential voltage. In case that the pixel electrodes AE1, AE2, and AE3 receive voltages corresponding to data voltages and the common electrodes CE1, CE2, and CE3 receive a low potential voltage, a potential difference may be formed between the pixel electrodes AE1, AE2, and AE3 and the common electrode CE1, CE2, and CE3. Accordingly, the light emitting layers EL1, EL2, and EL3 may emit light.

The common electrodes CE1, CE2, and CE3 may include the first common electrode CE1, the second common electrode CE2, and the third common electrode CE3 disposed in different emission areas EA1, EA2, and EA3. The first common electrode CE1 may be disposed on the first light emitting layer EL1 in the first emission area EA1, the second common electrode CE2 may be disposed on the second light emitting layer EL2 in the second emission area EA2, and the third common electrode CE3 may be disposed on the third light emitting layer EL3 in the third emission area EA3.

Like the light emitting layers EL1, EL2, and EL3, the common electrodes CE1, CE2, and CE3 may be formed by a deposition process. The deposition process of the common electrodes CE1, CE2, and CE3 may be performed such that an electrode material may be deposited in a direction inclined to an upper surface of the substrate SUB rather than in a direction perpendicular to the upper surface of the substrate SUB.

The capping layers CAP may be disposed on the common electrodes CE1, CE2, and CE3. The capping layers CAP may include an inorganic insulating material to cover pattern layers disposed on the light emitting elements ED1, ED2, and ED3. The capping layers CAP may prevent the light emitting elements ED1, ED2, and ED3 from being damaged by outside air. In an embodiment, the capping layers CAP may include an organic material such as a-NPD, NPB, TPD, m-MTDATA, Alq₃, LiF, and/or CuPc or may include an inorganic material such as aluminum oxide, titanium oxide, tantalum oxide, hafnium oxide, zinc oxide, silicon oxide, silicon nitride, and/or silicon oxynitride.

The display device 10 may include the bank structure. BNS disposed on the inorganic insulating layer IL. The bank structure BNS may have a structure in which the bank layers BN1 and BN2 including different materials are sequentially stacked. For example, the bank structure BNS may include openings including the emission areas EA1, EA2, and EA3 and may overlap the light blocking layer BM which will be described later. The light emitting elements ED1, ED2, and ED3 of the display device 10 may overlap the openings of the bank structure BNS.

The bank structure BNS may include the first bank layer BN1 disposed on the inorganic insulating layer IL and the second bank layer BN2 disposed on the first bank layer BN1.

The first bank layer BN1 may be disposed on the inorganic insulating layer IL. Side surfaces of the first bank layer BN1 may be more recessed than side surfaces of the inorganic insulating layer IL in a direction opposite to a direction toward the emission areas EA1, EA2, and EA3. The side surfaces of the first bank layer BN1 may be more recessed than side surfaces of the second bank layer BN2 to be described later in the direction opposite to the direction toward the emission areas EA1, EA2, and EA3.

According to an embodiment, the first bank layer BN1 may include a metal material. The metal material of the first bank layer BN1 may be any material that is removed together with the second bank layer BN2 by a dry etching process but may form an undercut structure by showing a different etch rate from the second bank layer BN2 for an alkali-based etchant or a fluorine-based etchant. The first bank layer BN1 may include aluminum (Al).

In an embodiment, a thickness of the first bank layer BN1 may be in a range of about 4,000 Å to about 10,000 Å. According to an example, the thickness of the first bank layer BN1 may be in a range of about 6,000 Å to about 8,000 Å. In case that the above range is satisfied, the light emitting layers EL1, EL2, and EL3 and the common electrodes CE1, CE2, and CE3 separated from each other may be formed by a deposition process and an etching process rather than a mask process.

According to an embodiment, the common electrodes CE1, CE2, and CE3 may contact (e.g., directly contact) the side surfaces of the first bank layer BN1. The common electrodes CE1, CE2, and CE3 of different light emitting elements ED1, ED2, and ED3 may contact (e.g., directly contact) the first bank layer BN1, and the first bank layer BN1 may include a metal material. Therefore, the common electrodes CE1, CE2, and CE3 may be connected (e.g., electrically connected) to each other through the first bank layer BN1.

The light emitting layers EL1, EL2, and EL3 may contact (e.g., directly contact) the side surfaces of the first bank layer BN1. The area of contact between the common electrodes CE1, CE2, and CE3 and the side surfaces of the first bank layer BN1 may be larger than the area of contact between the light emitting layers EL1, EL2, and EL3 and the side surfaces of the first bank layer BN1. The common electrodes CE1, CE2, and CE3 may be disposed on a larger area of the side surfaces of the first bank layer BN1 or may be disposed to a higher position on the side surfaces of the first bank layer BN1 than the light emitting layers EL1, EL2, and EL3. Since the common electrodes CE1, CE2, and CE3 of different light emitting elements ED1, ED2, and ED3 are connected (e.g., electrically connected) through the first bank layer BN1, it may be advantageous for the common electrodes CE1, CE2, and CE3 to contact a larger area of the first bank layer BN1. For example, the light emitting layers EL1, EL2, and EL3 may also not directly contact the side surfaces of the first bank layer BN1.

The second bank layer BN2 may be disposed on the first bank layer BN1. The second bank layer BN2 may include tip portions TIP that protrude as compared with the first bank layer BN1. The side surfaces of the second bank layer BN2 may protrude more than the side surfaces of the first bank layer BN1 toward the emission areas EA1, EA2, and EA3.

Since the side surfaces of the second bank layer BN2 protrude more than the side surfaces of the first bank layer BN1 toward the emission areas EA1, EA2, and EA3, an undercut structure of the first bank layer BN1 may be formed under each tip portion TIP of the second bank layer BN2.

The side shape of the first and second bank layers BN1 and BN2 may be a structure formed in an etching process due to a difference in etch rate between the first bank layer BN1 and the second bank layer BN2 including different materials. According to an embodiment, the second bank layer BN2 may include a material having a slower etch rate than the first bank layer BN1, and the first bank layer BN1 may be further etched during the etching process to form an undercut under each tip portion TIP of the second bank layer BN2.

In an embodiment, the first bank layer BN1 may include aluminum (Al), and the second bank layer BN2 may include titanium (Ti) or molybdenum (Mo). In case that the second bank layer BN2 includes titanium (Ti) or molybdenum (Mo), an etch selectivity for forming an undercut structure may be high. Molybdenum (Mo) may have a high etch selectivity for an insulating layer with respect to titanium (Ti).

In a fabrication process of the display device 10, a mask process may be used to form a pixel defining layer, which forms the emission areas EA1, EA2, and EA3, using an organic material or to form the light emitting layers EL1, EL2, and EL3 of the light emitting elements ED1, ED2, and ED3 in the emission areas EA1, EA2, and EA3, respectively. The display device 10 may be required to have a structure for holding a mask to perform a mask process or may be required to have an unnecessarily wide non-display area NDA to control distribution according to the mask process. In case that such a mask process is minimized, an unnecessary component, for example, a structure for holding a mask may be omitted from the display device 10, and the area of the non-display area NDA for distribution control may be minimized.

In the display device 10 according to an embodiment, since the bank structure BNS includes the tip portions TIP protruding toward the emission areas EA1, EA2, and EA3, it may be formed by a deposition process and an etching process rather than a mask process. For example, different layers may be separately formed in different emission areas EA1, EA2, and EA3 although a deposition process is performed. For example, in case that the light emitting layers EL1, EL2, and EL3 and the common electrodes CE1, CE2, and CE3 of the light emitting elements ED1, ED2, and ED3 are formed by a deposition process that does not use a mask, deposited materials may not be connected between the emission areas EA1, EA2, and EA3 but may be separated by the tip portions TIP of the second bank layer BN2 with the bank structure BNS interposed between the emission areas EA1, EA2, and EA3. After a material for forming a specific layer is formed on the entire surface of the display device 10, the layer formed in unwanted areas may be removed by an etching process. By this process, different layers may be separately formed in different emission areas EA1, EA2, and EA3. In the display device 10, it is possible to form different light emitting elements ED1, ED2, and ED3 in the emission areas EA1, EA2, and EA3, respectively, by a deposition process and an etching process without using a mask process, possible to omit an unnecessary component from the display device 10, and possible to minimize the area of the non-display area NDA.

In an embodiment, a thickness of the second bank layer BN2 may range from about 500 Å to about 3,000 Å. In an embodiment, in the second bank layer BN2, the tip portions TIP protruding from the first bank layer BN1 toward the emission areas EA1, EA2, and EA3 may have a width of about 0.1 μm to about 1.0 μm.

The tip portions TIP of the second bank layer BN2 may overlap the common electrodes CE1, CE2, and CE3 in the thickness direction DR3 of the substrate SUB. For example, the tip portions TIP of the second bank layer BN2 may overlap the light emitting layers EL1, EL2, and EL3 in a direction DR3 perpendicular to the substrate SUB. For example, the tip portions TIP of the second bank layer BN2 may overlap the inorganic insulating layer IL in the direction DR3 perpendicular to the substrate SUB. The common electrodes CE1, CE2, and CE3 may be formed under lower surfaces of the tip portions TIP of the second bank layer BN2. A maximum distance from the substrate SUB to the common electrodes CE1, CE2, and CE3 may be smaller than a maximum distance from the substrate SUB to the second bank layer BN2.

According to an embodiment, a protruding length of the second bank layer BN2 may be smaller than a protruding length of the inorganic insulating layer IL. For example, the protruding length of the second bank layer BN2 refers to a length (i.e., the width of each tip portion TIP) by which the side surfaces of the second bank layer BN2 protrude as compared with the side surfaces of the first bank layer BN1, and the protruding length of the inorganic insulating layer IL refers to a length by which the side surfaces of the inorganic insulating layer IL protrude as compared with the side surfaces of the first bank layer BN1.

The thin-film encapsulation layer TFEL may be disposed on the light emitting elements ED1, ED2, and ED3 and the bank structure BNS and may cover the light emitting elements ED1, ED2, and ED3 and the bank structure BNS. The thin-film encapsulation layer TFEL may include at least one inorganic layer to prevent oxygen or moisture from penetrating (or permeating) into the light emitting element layer EML. The thin-film encapsulation layer TFEL may include at least one organic layer to protect the light emitting element layer EML from foreign substances such as dust.

In an embodiment, the thin-film encapsulation layer TFEL may include the lower inorganic encapsulation layers TFE1, the organic encapsulation layer TFE2, and the upper organic encapsulation layer TFE3 stacked sequentially.

The lower inorganic encapsulation layers TFE1 may be disposed on the light emitting elements ED1, ED2, and ED3. The lower inorganic encapsulation layers TFE1 may include the first inorganic encapsulation layer TL1, the second inorganic encapsulation layer TL2, and the third inorganic encapsulation layer TL3 disposed to correspond to (or to overlap) different emission areas EA1, EA2, and EA3, respectively.

The first inorganic encapsulation layer TL1, the second inorganic encapsulation layer TL2, and the third inorganic encapsulation layer TL3 may include an inorganic insulating material to cover the light emitting elements ED1, ED2, and ED3, respectively. The first inorganic encapsulation layer TL1, the second inorganic encapsulation layer TL2, and the third inorganic encapsulation layer TL3 may prevent penetration (or permeation) of moisture from the outside and prevent damage to the light emitting elements ED1, ED2, and ED3. In an embodiment, the first inorganic encapsulation layer TL1, the second inorganic encapsulation layer TL2, and the third inorganic encapsulation layer TL3 may include aluminum oxide, titanium oxide, tantalum oxide, hafnium oxide, zinc oxide, silicon oxide, silicon nitride, and/or silicon oxynitride.

Since the first inorganic encapsulation layer TL1, the second inorganic encapsulation layer TL2, and the third inorganic encapsulation layer TL3 may be formed by a chemical vapor deposition (CVD) process, they may be formed to a uniform thickness along a step of a deposited layer. For example, each of the first inorganic encapsulation layer TL1, the second inorganic encapsulation layer TL2, and the third inorganic encapsulation layer TL3 may form a thin layer under an undercut formed by a tip portion TIP of the bank structure BNS.

The first inorganic encapsulation layer TL1 may be disposed on an upper surface of the first common electrode CE1, the side surfaces of the first bank layer BN1 and the lower and side surfaces of the second bank layer BN2, but may be spaced apart from the side surfaces of the second bank layer BN2. The first inorganic encapsulation layer TL1 may be disposed only in the first emission area EA1 without overlapping the second emission area EA2 and the third emission area EA3.

The second inorganic encapsulation layer TL2 may be disposed on an upper surface of the second common electrode CE2, the side surfaces of the first bank layer BN1 and the lower and side surfaces of the second bank layer BN2, but may be spaced apart from the side surfaces of the second bank layer BN2. The second inorganic encapsulation layer TL2 may be disposed only in the second emission area EA2 without overlapping the first emission area EA1 and the third emission area EA3.

The third inorganic encapsulation layer TL3 may be disposed on an upper surface of the third common electrode CE3, the side surfaces of the first bank layer BN1 and the lower and side surfaces of the second bank layer BN2, but may be spaced apart from the side surfaces of the second bank layer BN2. The third inorganic encapsulation layer TL3 may be disposed only in the third emission area EA3 without overlapping the first emission area EA1 and the second emission area EA2.

The first, second, and third inorganic encapsulation layers TL1, TL2, and TL3 may be spaced apart from each other. The second bank layer BN2 and the organic encapsulation layer TFE2 may be disposed in a space between the first inorganic encapsulation layer TL1 and the second inorganic encapsulation layer TL2.

In an embodiment, the lower inorganic encapsulation layers TL1, TL2, and TL3 may include one or more of silicon nitrate (SiNₓ), silicon oxynitride (SiNₓN_{y}), and silicon oxide (SiNₓ).

The maximum distance h1 from an upper surface of the substrate SUB to an upper surface of the second bank layer BN2 may be greater than or equal to a maximum distance h2 from the upper surface of the substrate SUB to upper surfaces of the lower inorganic encapsulation layers TL1, TL2, and TL3. For example, the maximum distance h1 from the upper surface of the substrate SUB to the upper surface of the second bank layer BN2 and the maximum distance h2 from the upper surface of the substrate SUB to the upper surface of the first inorganic encapsulation layer TL1 are partially illustrated for the sake of understanding.

According to an embodiment, the lower inorganic encapsulation layers TL1, TL2, and TL3 may be aligned with the upper surface of the second bank layer BN2 or may be disposed below the upper surface of the second bank layer BN2. The lower inorganic encapsulation layers TL1, TL2, and TL3 may not exist (or may not be disposed) on the second bank layer BN2. An upper surface of the first bank layer BN1 may not overlap the lower inorganic encapsulation layers TL1, TL2, and TL3 in the direction DR3 perpendicular to the substrate SUB.

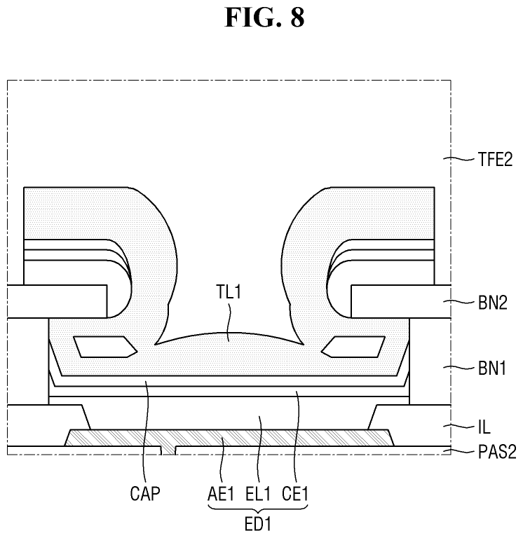

As illustrated in FIG. 8, trace pattern layers of the light emitting layers EL1, EL2, and EL3, trace pattern layers of the common electrodes CE1, CE2, and CE3, trace pattern layers of the capping layers CAP, and the first inorganic encapsulation layer TL1 may be disposed on the second bank layer BN2. The trace pattern layers may be formed on the bank structure BNS in case that the light emitting layers EL1, EL2, and EL3 and the common electrodes CE1, CE2, and CE3 of the light emitting elements ED1, ED2, and ED3 are deposited. In case that the trace pattern layers and the first inorganic encapsulation layer TL1 remain on the second bank layer BN2, the remained trace pattern layers and the remained first inorganic encapsulation layer TL1 may be peeled off in a subsequent cleaning process. For example, the trace pattern layers and the first inorganic encapsulation layer TL1 on the second bank layer BN2 may be deformed by physical force. Accordingly, the penetration (or permeation) of moisture from the outside may not be completely blocked, and the display device 10 may be damaged.

In case that the lower inorganic encapsulation layers TL1, TL2, and TL3 do not exist (or are not disposed) on the second bank layer BN2, there is no structural deformation in a subsequent cleaning process, thereby improving stability.

Each of the lower inorganic encapsulation layers TL1, TL2, and TL3 may include a first portion TP1, a second portion TP2, a third portion TP3, and a fourth portion TP4. The first portion TP1 may be disposed on the upper surface of the common electrode CE1, CE2 or CE3. The second portion TP2 may be disposed on the side surfaces of the second bank layer BN2 but spaced apart from the side surfaces of the second bank layer BN2. The third portion TP3 may extend from the second portion TP2 and may contact the lower surface of the second bank layer BN2. The fourth portion TP4 may extend from the first portion TP1 and the third portion TP3 and may contact the side surfaces of the first bank layer BN1.

The first portion TP1 and the second portion TP2 of each of the lower inorganic encapsulation layers TL1, TL2, and TL3 may be connected to each other. The first portion TP1 and the second portion TP2 may be bonded to each other. The first portion TP1 and the second portion TP2 connected to each other may be structurally stable. For example, the first portion TP1 and the second portion TP2 connected to each other may prevent moisture introduced (or permeated) between the second bank layer BN2 and the organic encapsulation layer TFE2 from entering the light emitting elements ED1, ED2, and ED3.

The third portion TP3 of each of the lower inorganic encapsulation layers TL1, TL2, and TL3 may contact an exposed portion of the lower surface of the second bank layer BN2, e.g., the lower surfaces of the tip portions TIP. The third portion TP3 may contact the entire lower surfaces of the tip portions TIP to prevent moisture introduced (or permeated) from the outside from entering the light emitting elements.

The fourth portion TP4 of each of the lower inorganic encapsulation layers TL1, TL2, and TL3 may be disposed on the side surfaces of the first bank layer BN1 and may be disposed on the common electrode CE1, CE2 or CE3 and a capping layer CAP. The fourth portion TP4 may contact the side surfaces of the first bank layer BN1 and the side surfaces (or inclined surfaces) the capping layer CAP.

A cavity CVT surrounded by the first through fourth portions TP1, TP2, TP3, and TP4 of each of the lower inorganic encapsulation layer TL1, TL2, and TL3 may be formed. The cavity CVT may be surrounded by each of the lower inorganic encapsulation layers TL1, TL2, and TL3 in all directions (e.g., DR3, DR4 and DR5). The cavity CVT may be positioned under each tip portion TIP of the second bank layer BN2 and thus may not significantly affect the path of light emitted from the light emitting layer EL1, EL2 or EL3.

Since the first portion TP1 and the second portion TP2 are connected to each other, a space surrounded by each of the lower inorganic encapsulation layers TL1, TL2, and TL3 in all directions except for the direction DR4 perpendicular to the substrate SUB may be created. This space may be in the form of a groove, a trench, a concave portion, or a depression. The groove may be defined by the first portion TP1 and the second portion TP2.

The fillers FIL1, FIL2, and FIL3 may be disposed in the grooves defined by the first portions TP1 and the second portions TP2 of the lower inorganic encapsulation layers TL1, TL2, and TL3. The fillers FIL1, FIL2, and FIL3 may be disposed in the grooves to support the structure of the lower inorganic encapsulation layers TL1, TL2, and TL3.

The first filler FIL1 may be disposed in a groove defined by the first portion TP1 and the second portion TP2 of the first inorganic encapsulation layer TL1, the second filler FIL2 may be disposed in a groove defined by the first portion TP1 and the second portion TP2 of the second inorganic encapsulation layer TL2, and the third filler FIL3 may be disposed in a groove defined by the first portion TP1 and the second portion TP2 of the third inorganic encapsulation layer TL3. The first, second, and third fillers FIL1, FIL2, and FIL3 may be spaced apart from each other.

Upper surfaces of the fillers FIL1, FIL2, and FIL3 may be aligned (or coplanar) with upper surfaces of the lower inorganic encapsulation layers TL1, TL2, and TL3 to form a flat surface. The upper surfaces of the fillers FIL1, FIL2, and FIL3 and the upper surfaces of the lower inorganic encapsulation layers TL1, TL2, and TL3 may be smoothly connected without large irregularities. The upper surfaces of the fillers FIL1, FIL2, and FIL3, the upper surfaces of the lower inorganic encapsulation layers TL1, TL2, and TL3, and the upper surface of the second bank layer BN2 may be aligned (or coplanar) with each other to form a flat surface.

In an embodiment, the fillers FIL1, FIL2, and FIL3 may include spin-on glass (SOG). The spin-on glass (SOG) may have a light transmittance of about 100% and includes silicon oxide (SiNₓ) and polyimide. The silicon oxide may be a main component, and the polyimide may be added to improve coating properties. The spin-on glass (SOG) may be suitable for filling grooves flat.

In an embodiment, the fillers FIL1, FIL2, and FIL3 may have a refractive index of about 1.45 to about 1.60. In an embodiment, the refractive index of each of the fillers FIL1, FIL2, and FIL3 may be in a range of about 1.50 to about 1.55. In case that the above range is satisfied, the light loss may be small because the refractive indices of the fillers FIL1, FIL2, and FIL3 are similar to refractive indices of the organic encapsulation layer TFE2 and the upper inorganic encapsulation layer TFE3 disposed on the fillers FIL1, FIL2, and FIL3.

The organic encapsulation layer TFE2 may be disposed on the second bank layer BN2, the lower inorganic encapsulation layers TL1, TL2, and TL3, and the fillers FIL1, FIL2, and FIL3.

Spaces between the side surfaces of the second bank layer BN2 and the second portions TP2 of the lower inorganic encapsulation layers TL1, TL2, and TL3 may be filled with the organic encapsulation layer TFE2. The organic encapsulation layer TFE2 may contact the side surfaces of the second bank layer BN2.

The upper surface of the second bank layer BN2 may contact the organic encapsulation layer TFE2. Upper surfaces of the tip portions TIP of the second bank layer BN2 may contact the organic encapsulation layer TFE2. The entire upper surface of the second bank layer BN2 may contact the organic encapsulation layer TFE2.

The organic encapsulation layer TFE2 may include a polymer-based material. Examples of the polymer-based material may include acrylic resin, epoxy resin, polyimide, and polyethylene. For example, the organic encapsulation layer TFE2 may include acrylic resin such as polymethyl methacrylate or polyacrylic acid. The organic encapsulation layer TFE2 may be formed by curing a monomer or by applying a polymer.

The upper inorganic encapsulation layer TFE3 may include one or more inorganic insulating materials. The inorganic insulating materials may be any one of silicon oxide, silicon nitride, and silicon oxynitride, for example, may be aluminum oxide, titanium oxide, tantalum oxide, hafnium oxide, zinc oxide, silicon oxide, silicon nitride, and/or silicon oxynitride.

The light blocking layer BM may be disposed on the thin-film encapsulation layer TFEL. The light blocking layer BM may include holes OPT1, OPT2, and OPT3 disposed to overlap the emission areas EA1, EA2, and EA3. For example, a first hole OPT1 may overlap the first emission area EA1. A second hole OPT2 may overlap the second emission area EA2, and a third hole OPT3 may overlap the third emission area EA3. The areas (or sizes) of the holes OPT1, OPT2, and OPT3 may be larger than the areas (or sizes) of the emission areas EA1, EA2, and EA3, respectively. Since the holes OPT1, OPT2, and OPT3 of the light blocking layer BM are formed to be larger than the emission areas EA1, EA2, and EA3, light emitted from the emission areas EA1, EA2, and EA3 may be seen (or recognized) by a user not only from the front but also from the side of the display device 10.

The light blocking layer BM may include a light absorbing material. For example, the light blocking layer BM may include an inorganic black pigment or an organic black pigment. The inorganic black pigment may be carbon black, and the organic black pigment may include at least one of lactam black, perylene black, and aniline black. However, embodiments are not limited thereto. The light blocking layer BM may prevent color mixing by preventing intrusion of visible light between the first, second, and third emission areas EA1, EA2, and EA3, thereby improving a color gamut of the display device 10.

The display device 10 may include color filters CF1, CF2, and CF3 disposed on the emission areas EA1, EA2, and EA3. The color filters CF1, CF2, and CF3 may be disposed to correspond to the emission areas EA1, EA2, and EA3, respectively. For example, the color filters CF1, CF2, and CF3 may be disposed on the light blocking layer BM including the holes OPT1, OPT2, and OPT3 corresponding to the emission areas EA1, EA2, and EA3. The holes OPT1, OPT2, and OPT3 of the light blocking layer BM may be formed to overlap the emission areas EA1, EA2, and EA3 or the openings of the bank structure BNS and may form light output areas through which light emitted from the emission areas EA1, EA2, and EA3 is output. The color filters CF1, CF2, and CF3 may have a larger area than the holes OPT1, OPT2, and OPT3 of the light blocking layer BM, respectively. The color filters CF1, CF2, and CF3 may cover (e.g., completely cover) the light output areas formed by the holes OPT1, OPT2, and OPT3, respectively.

The color filters CF1, CF2, and CF3 may include a first color filter CF1, a second color filter CF2, and a third color filter CF3 disposed to correspond to different emission areas EA1, EA2, and EA3, respectively. Each of the color filters CF1, CF2, and CF3 may include a colorant such as a dye or pigment that absorbs light in wavelength bands other than light in a specific wavelength band and may be disposed to correspond to the color of light emitted from one of the emission areas EA1, EA2, and EA3. For example, the first color filter CF1 may be a red color filter that overlaps the first emission area EA1 and selectively transmits red light (or first color light). The second color filter CF2 may be a green color filter that overlaps the second emission area EA2 and selectively transmits green light (or second color light), and the third color filter CF3 may be a blue color filter that overlaps the third emission area EA3 and selectively transmits blue light (or third color light).

Each of the color filters CF1, CF2, and CF3 may be spaced apart from other adjacent color filters CF1, CF2, and CF3 on the light blocking layer BM. The color filters CF1, CF2, and CF3 may cover the holes OPT1, OPT2, and OPT3 of the light blocking layer BM and have a larger area than the holes OPT1, OPT2, and OPT3, respectively. The color filters CF1, CF2, and CF3 may be spaced apart from each other. For example, parts (or portions) of the color filters CF1, CF2, and CF3, which are disposed on the light blocking layer BM, may be spaced apart from each other in the fourth direction DR4. However, embodiments are not limited thereto. In another example, each of the color filters CF1, CF2, and CF3 may also partially overlap adjacent color filters CF1, CF2, and CF3. The color filters CF1, CF2, and CF3 may not overlap each other in the emission areas EA1, EA2, and EA3 and may overlap each other on the light blocking layer BM which will be described later. Since the color filters CF1, CF2, and CF3 overlap each other in the display device 10, the intensity of reflected light due to external light may be reduced. Further, the color of reflected light due to external light may be controlled by adjusting the arrangement, shapes, and areas of the color filters CF1, CF2, and CF3 in plan view.

The overcoat layer OC may be disposed on the color filters CF1, CF2, and CF3 to planarize upper end portions of the color filters CF1, CF2, and CF3. The overcoat layer OC may be a colorless light-transmitting layer that does not have a color in a visible light band. For example, the overcoat layer OC may include a colorless light-transmitting organic material such as acrylic resin.

A process of fabricating the display device 10 according to the embodiment will now be described with reference to other drawings.

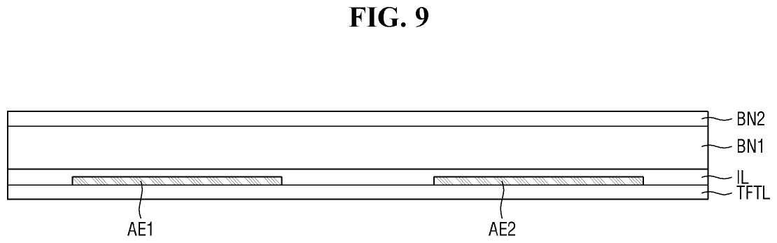

FIGS. 9, 10, 11, 12, 13, 14, 15, 16, and 17 are schematic cross-sectional views sequentially illustrating a process of fabricating a display device according to an embodiment. FIGS. 9, 10, 11, 12, 13, 14, 15, 16, and 17 schematically illustrate a process of forming a bank structure BNS and light emitting elements ED as a light emitting element layer EML of the display device 10 and a thin-film encapsulation layer TFEL. In the following description of the process of fabricating the display device 10, the formation process of each layer will not be described, and the formation order of each layer will be described.

Referring to FIG. 9, pixel electrodes AE1, AE2, and AE3 spaced apart from each other, an inorganic insulating material layer IL, and bank material layers BN1 and BN2 may be formed on a thin-film transistor layer TFTL.

For example, the thin-film transistor layer TFTL may be disposed on a substrate SUB. The structure of the thin-film transistor layer TFTL is the same as that described above with reference to FIG. 6, and thus a detailed description thereof will be omitted for descriptive convenience.

The inorganic insulating material layer IL and the bank material layers BN1 and BN2 may be disposed on the pixel electrodes AE1, AE2, and AE3. The inorganic insulating material layer IL may be disposed to cover (e.g., entirely cover) the thin-film transistor layer TFTL, and first and second bank material layers BN1 and BN2 may be disposed to cover (e.g., entirely cover) the inorganic insulating material layer IL. The bank material layers BN1 and BL2 may be partially etched in a subsequent process to respectively form bank layers BN1 and BN2 of the bank structure BNS illustrated in FIG. 6.

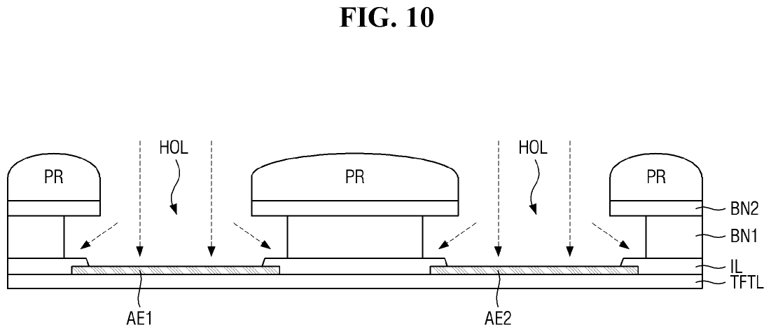

Referring to FIG. 10, photoresists PR may be formed on the bank material layers BN1 and BN2, and a first etching process may be performed by using the photoresists PR as a mask to partially etch the first and second bank material layers BN1 and BN2 such that holes HOL may be formed therein.

The photoresists PR may be spaced apart from each other on the bank material layers BN1 and BN2. The photoresists PR may be disposed on the second bank material layer BN2 to expose portions overlapping first, second, and third pixel electrodes AE1, AE2, and AE3.

In an embodiment, the first etching process may be performed as a dry etching process. Since the first etching process is performed as a dry etching process, the first and second bank material layers BN1 and BN2 including different materials may be anisotropically etched. In the current process, the first and second bank material layers BN1 and BN2 may be etched together to partially expose the pixel electrodes AE1, AE2, and AE3. The holes HOL may be formed in areas overlapping the pixel electrodes AE1, AE2, and AE3. The holes HOL may form openings of the bank structure BNS.

For example, the first and second bank material layers BN1 and BN2 may be isotropically etched in the holes HOL by a wet etching process (e.g., second etching process). The first bank material layer BN1 may be etched faster than the other bank material layer, and side surfaces of the second bank material layer BN2 may be formed to protrude more than side surfaces of the first bank material layer BN1. The side surfaces of the second bank material layer BN2 may protrude more than the side surfaces of the first bank material layer BN1 toward the holes HOL to form tip portions TIP, and an undercut may be formed under each tip portion TIP.

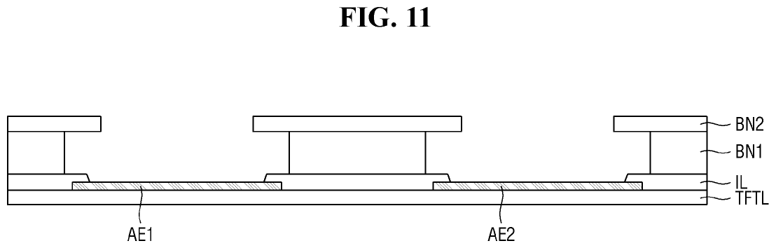

As illustrated in FIG. 11, the photoresists PR may be removed from a second bank layer BN2.

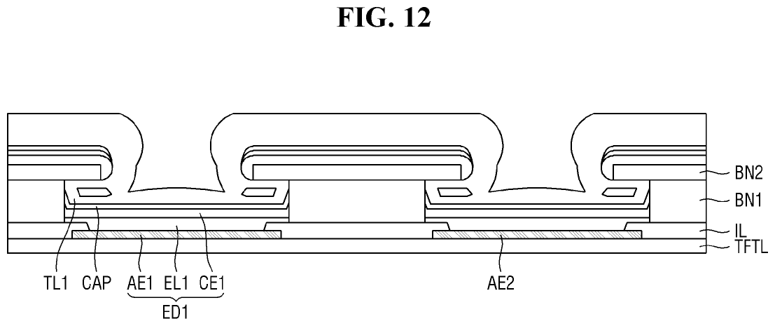

Referring to FIG. 12, a first light emitting element ED1 may be formed by depositing a first light emitting layer EL1, a first common electrode CE1, and a capping layer CAP on the first pixel electrode AE1. For example, the first light emitting layer EL1, the first common electrode CE1, and the capping layer CAP may be formed on the entire surface of the bank structure BNS. Therefore, the first light emitting layer EL1, the first common electrode CE1, and the capping layer CAP may be formed not only on the first pixel electrode AE1 but also in an opening overlapping the second pixel electrode AE2. Materials that form the first light emitting layer EL1 and the first common electrode CE1 may also be formed on the second bank layer BN2 to form trace pattern layers.

The first light emitting layer EL1 and the first common electrode CE1 may be formed by a deposition process. In a first opening, materials may not be smoothly deposited due to the tip portions TIP of the second bank layer BN2. However, since the materials of the first light emitting layer EL1 and the first common electrode CE1 are deposited in a direction inclined to an upper surface of the substrate SUB rather than in a direction perpendicular to the upper surface of the substrate SUB, the materials of the first light emitting layer EL1 and the first common electrode CE1 may be deposited in areas covered by the tip portions TIP of the second bank layer BN2.

A deposition process for forming the common electrodes CE1, CE2, and CE3 may be performed at an angle relatively closer to a horizontal direction than a deposition process for forming the light emitting layers EL1, EL2, and EL3. Accordingly, the common electrodes CE1, CE2, and CE3 may contact side surfaces of the second bank layer BN2 over a larger area than the light emitting layers EL1, EL2, and EL3. In another example, the common electrodes CE1, CE2, and CE3 may be deposited to a higher position on the side surfaces of the second bank layer BN2 than the light emitting layers EL1, EL2, and EL3. The different common electrodes CE1, CE2, and CE3 may be electrically connected to each other by contacting the second bank layer BN2 having high conductivity.

For example, a first inorganic encapsulation layer TL1 may be formed to cover the first light emitting element ED1 and the capping layer CAP. The first inorganic encapsulation layer TL1 may be formed to cover (e.g., completely cover) outer surfaces of the first light emitting element ED1, the bank layers BN1 and BN2, the capping layer CAP, and the trace pattern layers. For example, the first inorganic encapsulation layer TL1 may be formed on an upper surface of the first common electrode CE1, side surfaces of the first bank layer BN1, lower and side surfaces of the second bank layer BN2, and upper and side surfaces of the trace pattern layers. For example, a second portion TP2 of the first inorganic encapsulation layer TL1 which is formed on the side surfaces of the second bank layer BN2 (e.g., the side surfaces of the trace pattern layers) may be bonded to a first portion TP1 of the first inorganic encapsulation layer TL1 which is formed on the upper surface of the first common electrode CE1. The first portion TP1 of the first inorganic encapsulation layer TL1 and the second portion TP2 of the first inorganic encapsulation layer TL1 may form a groove.

In an embodiment, the first inorganic encapsulation layer TL1 may include one or more of silicon nitrate (SiNₓ), silicon oxynitride (SiNₓN_{y}), and silicon oxide (SiNₓ).

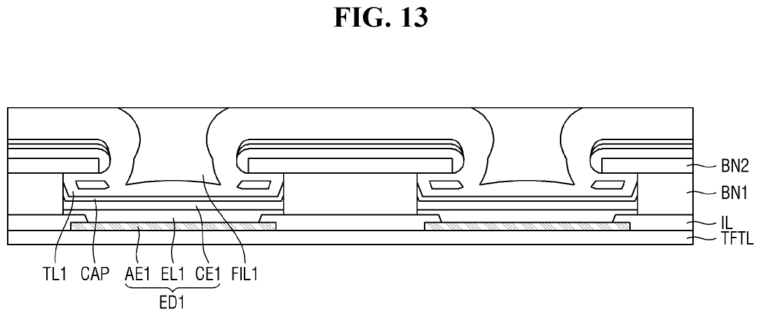

Referring to FIG. 13, the groove formed by the first portion TP1 of the first inorganic encapsulation layer TL1 and the second portion TP2 of the first inorganic encapsulation layer TL1 may be filled with a first filler FIL1. For example, the first filler FIL1 may include spin-on glass (SOG), and the groove may be filled with SOG coating to form a flat surface.

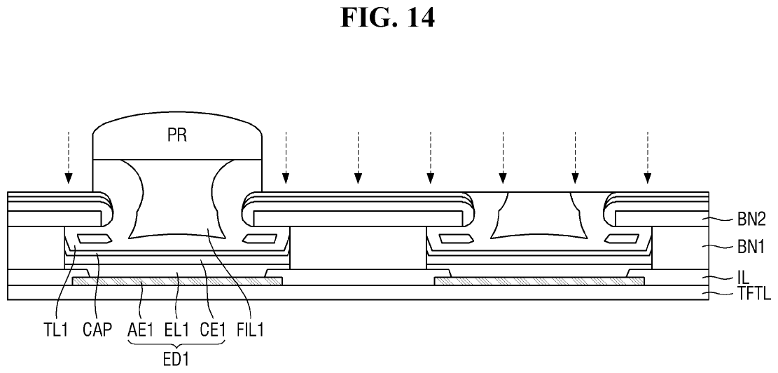

Referring to FIG. 14, a photoresist PR of a mask pattern layer may be formed on the first inorganic encapsulation layer TL1, and a third etching process may be performed to remove the first inorganic encapsulation layer TL1 and the first filler FIL1, which are not covered by the mask pattern layer. For example, the photoresist PR may be disposed to overlap a first emission area EA1 and an edge area surrounding the first emission area EA1. The first filler FIL1 including spin-on glass (SOG), of which main component is silicon oxide, may have an etch rate similar to that of the first inorganic encapsulation layer TL1. The first inorganic encapsulation layer TL1 and the first filler FIL1 may be anisotropically dry-etched until the first inorganic encapsulation layer TL1 on the second bank layer BN2 is removed. The trace pattern layers on the second bank layer BN2 may be exposed. A portion of the first inorganic encapsulation layer TL1 and the filler FIL1 may remain on the second pixel electrode AE2. For example, upper surfaces of the remaining first inorganic encapsulation layer TL1 and the remaining first filler FIL1 may be disposed at a similar height to the upper surfaces of the trace pattern layers on the second bank layer BN2.

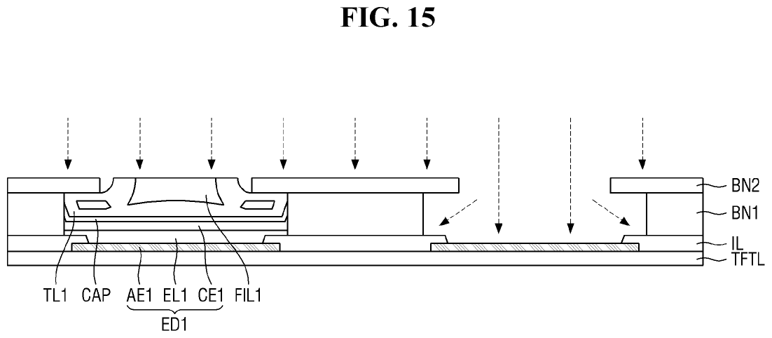

Referring to FIG. 15, the first inorganic encapsulation layer TL1 and the first filler FIL1 covered by the mask pattern layer may be partially etched while the remaining first inorganic encapsulation layer TL1 and first filler FIL1, which are not covered by the mask pattern layer, are etched.

The first inorganic encapsulation layer TL1 and the first filler FIL1 remaining on the second pixel electrode AE2 may be removed by an isotropic dry etching process (e.g., fourth etching process), and the first light emitting layer EL1 and the first common electrode CE1, which are not covered by the mask pattern layer, may be removed by a wet etching process during the dry etching process. The trace pattern layers disposed on the side surfaces of the second bank layer BN2 may also be removed. The photoresist PR may also be removed by the isotropic dry etching process. The first inorganic encapsulation layer TL1 and the first filler TIL in an area, in which the photoresist PR is disposed, may be partially etched, and upper surfaces of the first inorganic encapsulation layer TL1 and the first filler FIL1 on the first pixel electrode AE1 may be aligned (or coplanar) with an upper surface of second bank layer BN2 to form a flat surface.

In the current process, the upper surface of the second bank layer BN2, the second pixel electrode AE2, the first filler FIL1, and the first inorganic encapsulation layer TL1 may be exposed.

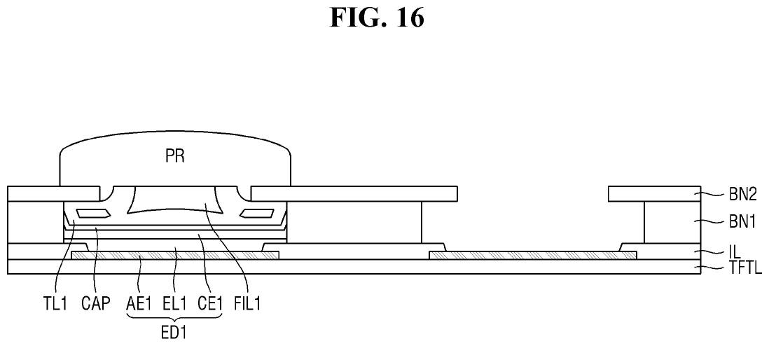

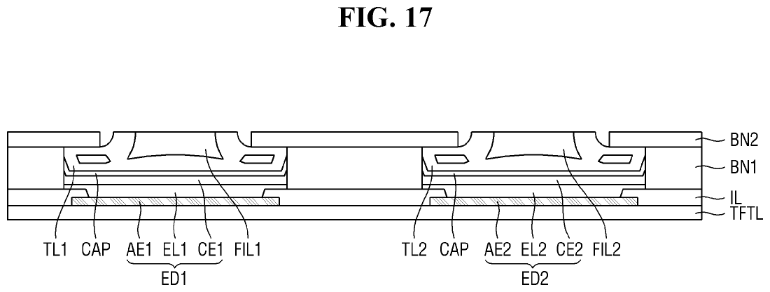

Referring to FIGS. 16 and 17, a photoresist PR may be placed on the first emission area EA1, and the same processes as those of FIGS. 12, 13, 14, and 15 are performed to form a second light emitting element ED2 and a capping layer CAP and form a second inorganic encapsulation layer TL2 and a second filler FIL2 covering them.

For example, an organic encapsulation layer TFE2 and a second inorganic encapsulation layer TFE3 of the thin-film encapsulation layer TFEL, a light blocking layer BM, a color filter layer CFL, and an overcoat layer OC may be formed on the light emitting elements ED1, ED2, and ED3 and the bank structure BNS to produce the display device 10. The structures of the thin-film encapsulation layer TFEL, the light blocking layer BM, the color filter layer CFL, and the overcoat layer OC may be the same as those described above, and thus a detailed description thereof will be omitted for descriptive convenience.

In a display device 10 and a method of fabricating the display device 10 according to an embodiment, a lower inorganic encapsulation layer (e.g., TL1, TL2, or TL3) may be aligned with an upper surface of a second bank layer BN1 or disposed below the upper surface of the second bank layer BN2. Therefore, stability of the lower inorganic encapsulation layer (e.g., TL1, TL2, or TL3) may be improved.

However, the effects of the disclosure are not restricted to the one set forth herein. The above and other effects of the disclosure will become more apparent to one of daily skill in the art to which the disclosure pertains by referencing the claims.

What is claimed is:

1. A display device comprising:
a first pixel electrode disposed on a substrate;
an inorganic insulating layer disposed on the substrate and exposing the first pixel electrode;
a first light emitting layer disposed on the first pixel electrode;
a first common electrode disposed on the first light emitting layer;
a first bank layer disposed on the inorganic insulating layer;
a second bank layer disposed on the first bank layer and including side surfaces protruding more than side surfaces of the first bank layer; and
a first inorganic encapsulation layer disposed on an upper surface of the first common electrode, the side surfaces of the first bank layer, and a lower surface and the side surfaces of the second bank layer, the first inorganic encapsulation layer spaced apart from the side surfaces of the second bank layer,
wherein a maximum distance from an upper surface of the substrate to an upper surface of the second bank layer is greater than or equal to a maximum distance from the upper surface of the substrate to an upper surface of the first inorganic encapsulation layer.

2. The display device of claim 1, wherein
the first inorganic encapsulation layer comprises:
a first portion disposed on the upper surface of the first common electrode, and
a second portion spaced apart from the side surfaces of the second bank layer, and
the first portion of the first inorganic encapsulation layer and the second portion of the first inorganic encapsulation layer are connected to each other.

3. The display device of claim 2, further comprising:
a first filler disposed in a groove defined by the first portion of the first inorganic encapsulation layer and the second portion of the first inorganic encapsulation layer.

4. The display device of claim 1, further comprising:
an organic encapsulation layer disposed on the second bank layer and the first inorganic encapsulation layer,
wherein the side surfaces of the second bank layer contact the organic encapsulation layer.

5. The display device of claim 4, wherein the upper surface of the second bank layer contacts the organic encapsulation layer.

6. The display device of claim 2, wherein the first inorganic encapsulation layer further comprises:
a third portion extending from the second portion and contacting a lower surface of the second bank layer,
a fourth portion extending from the first portion and the third portion and contacting the side surfaces of the first bank layer, and
a cavity surrounded by the first, second, third, and fourth portions of the first inorganic encapsulation layer.

7. The display device of claim 3, wherein an upper surface of the first filler is aligned with the upper surface of the first inorganic encapsulation layer to form a flat surface.

8. The display device of claim 3, wherein the first filler comprises spin-on-glass.

9. The display device of claim 8, wherein a refractive index of the first filler is in a range of about 1.45 to about 1.60.

10. The display device of claim 1, wherein an upper surface of the first bank layer does not overlap the first inorganic encapsulation layer in a direction perpendicular to the substrate.

11. The display device of claim 1, wherein
the first bank layer comprises aluminum (Al), and
the second bank layer comprises titanium (Ti) or molybdenum (Mo).

12. The display device of claim 1, wherein the first inorganic encapsulation layer comprises one or more of silicon nitrate (SiNₓ), silicon oxynitride (SiNₓN_{y}), and silicon oxide (SiNₓ).

13. A display device comprising:
a first pixel electrode disposed on a substrate;
an inorganic insulating layer disposed on the substrate and exposing the first pixel electrode;
a first light emitting layer disposed on the first pixel electrode;
a first common electrode disposed on the first light emitting layer;
a first bank layer disposed on the inorganic insulating layer;
a second bank layer disposed on the first bank layer and including side surfaces protruding more than side surfaces of the first bank layer;
a first inorganic encapsulation layer disposed on an upper surface of the first common electrode, the side surfaces of the first bank layer, and a lower surface and the side surfaces of the second bank layer, the first inorganic encapsulation layer spaced apart from the side surfaces of the second bank layer; and
an organic encapsulation layer disposed on the second bank layer and the first inorganic encapsulation layer, wherein
the organic encapsulation layer contacts an upper surface and the side surfaces of the second bank layer, and
an upper surface of the first bank layer does not overlap the first inorganic encapsulation layer in a direction perpendicular to the substrate.

14. The display device of claim 13, further comprising a first filler, wherein
the first inorganic encapsulation layer comprises:
a first portion disposed on the upper surface of the first common electrode, and
a second portion spaced apart from the side surfaces of the second bank layer,
the first portion of the first inorganic encapsulation layer and the second portion of the first inorganic encapsulation layer are connected to each other, and
the first filler is disposed in a groove defined by the first portion of the first inorganic encapsulation layer and the second portion of the first inorganic encapsulation layer.

15. The display device of claim 13, wherein the entire upper surface of the second bank layer contacts the organic encapsulation layer.

16. A method of fabricating a display device, the method comprising:
forming a plurality of pixel electrodes spaced apart from each other on a substrate;
forming an inorganic insulating material layer on the plurality of pixel electrodes;
forming a first bank material layer on the inorganic insulating material layer;
forming a second bank material layer on the first bank material layer;
forming holes which expose the plurality of pixel electrodes by etching the first bank material layer and the second bank material layer and etching side surfaces of the first bank material layer exposed in the holes to expose a portion of a lower surface of the second bank material layer;
forming a first light emitting layer on a first pixel electrode among the plurality of pixel electrodes and forming a first common electrode on the first light emitting layer;
forming a first inorganic encapsulation layer on the first common electrode;
coating a first filler on the first inorganic encapsulation layer;
forming a mask pattern layer on the first inorganic encapsulation layer overlapping the first pixel electrode and etching the first inorganic encapsulation layer and the first filler not covered by the mask pattern layer by an etching process; and
partially etching the first inorganic encapsulation layer and the first filler covered by the mask pattern layer.

17. The method of claim 16, wherein in the forming of the first inorganic encapsulation layer on the first common electrode,
the first inorganic encapsulation layer is formed on an upper surface of the first common electrode, the side surfaces of the first bank material layer, and the lower surface and side surfaces of the second bank material layer, and
the first inorganic encapsulation layer formed on the side surfaces of the second bank material layer is bonded to the first inorganic encapsulation layer formed on the upper surface of the first common electrode.

18. The method of claim 16, wherein in the forming of the mask pattern layer on the first inorganic encapsulation layer overlapping the first pixel electrode and the etching of the first inorganic encapsulation layer and the first filler not covered by the mask pattern layer by the etching process,
an anisotropic dry etching process is performed until the first inorganic encapsulation layer on the second bank material layer is removed, and
the first inorganic encapsulation layer and the first filler remain on a second pixel electrode.

19. The method of claim 18, wherein in the partially etching of the first inorganic encapsulation layer and the first filler covered by the mask pattern layer,
the first inorganic encapsulation layer on the second pixel electrode, the first filler, the first common electrode and the first light emitting layer are removed,
the mask pattern layer is removed,
the first inorganic encapsulation layer and the first filler are etched, and
upper surfaces of the first inorganic encapsulation layer and the first filler on the first pixel electrode are aligned with an upper surface of the second bank material layer to form a flat surface.

20. The method of claim 16, wherein
the first inorganic encapsulation layer comprises one or more of silicon nitrate (SiNₓ), silicon oxynitride (SiOₓN_{y}) and silicon oxide (SiOₓ), and
the first filler comprises spin-on-glass.
